(19) United States
(12) Patent Application Publication
(10) Pub. No.: US 2024/0355708 A1
(43) Pub. Date: Oct. 24, 2024

(54) BACKSIDE VIA AND METAL GATE SEPARATION

(71) Applicant: Taiwan Semiconductor Manufacturing Company, Ltd., Hsin-Chu (TW)

(72) Inventors: Po-Yu HUANG, Hsinchu (TW); Shih-Chieh WU, Hsinchu (TW); Chen-Ming LEE, Taoyuan County (TW); I-Wen WU, Hsinchu City (TW); Fu-Kai YANG, Hsinchu City (TW); Mei-Yun WANG, Hsinchu (TW)

(21) Appl. No.: 18/304,913

(22) Filed: Apr. 21, 2023

(51) Int. Cl. H01L 23/48; H01L 21/8238; H01L 27/092; H01L 29/06; H01L 29/423; H01L 29/66; H01L 29/775; H01L 29/786

(52) U.S. Cl. CPC H01L 23/481; H01L 21/823807; H01L 21/823814; H01L 21/823871; H01L 27/092; H01L 29/0673; H01L 29/42392; H01L 29/66439; H01L 29/66545; H01L 29/775; H01L 29/78696

(57) ABSTRACT

One aspect of the present disclosure pertains to a method of forming a semiconductor device. The method includes forming a gate stack over a channel region and forming a first source/drain (S/D) trench adjacent the channel region and extending into the substrate below a top surface of an isolation structure. The method includes forming a first epitaxial S/D feature in the first S/D trench and forming a first frontside metal contact over the first epitaxial S/D feature. The method further includes forming a first backside trench that exposes a bottom surface of the first epitaxial S/D feature and forming a first backside conductive feature in the first backside trench and on the exposed bottom surface of the first epitaxial S/D feature. A top surface of the first backside conductive feature is under a bottommost surface of the gate stack.

### BACKGROUND

The integrated circuit (IC) industry has experienced exponential growth. Technological advances in semiconductor manufacturing have produced generations of ICs, where each generation has smaller and more complex circuits than the previous generation. In the course of IC evolution, functional density (i.e., the number of interconnected IC devices per chip area) has generally increased while geometry size (i.e., dimensions and/or sizes of IC features and/or spacings between these IC features) has decreased. Typically, scaling down has been limited only by an ability to lithographically define IC features at the ever-decreasing geometry sizes.

As feature sizes continue to decrease, some IC features such as source/drain metal contacts and power line connections may be moved to the back side of the wafer. Moving these features allows for better spacing management while optimizing power consumption. To achieve this, source/drain features formed on the front side of the substrate must electrically connect to backside power rails through backside vias (or backside metal contacts). These backside vias need to have low resistance, low capacitance, and low leakage current for improved device performance. In some cases, leakage current becomes an issue when the backside via is not properly insulated. For example, there may be current leakage through a backside substrate material. This leakage must be minimized to avoid any coupling or short between metal gate and the source/drain metal contacts.

Therefore, although existing methods of forming backside vias have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIGS. 1A-1B is a flow chart of a method to form a semiconductor device having a backside via, in portion or in entirety, according to various aspects of the present disclosure.

FIGS. 2A-2B illustrate three-dimensional and top views of a semiconductor workpiece having lines A-A′ and B-B′ cut across source/drain regions of the workpiece.

FIGS. 3A-23A illustrate cross-sectional views of a semiconductor device cut along the lines A-A′ in FIGS. 2A-2B at intermediate stages of fabrication and processed in accordance with the method of FIGS. 1A-1B according to an embodiment of the present disclosure.

FIGS. 3B-4B, 10B-11B, and 15B-23B illustrate cross-sectional views of a semiconductor device cut along the lines B-B′ in FIGS. 2A-2B at intermediate stages of fabrication and processed in accordance with the method of FIGS. 1A-1B according to an embodiment of the present disclosure.

FIG. 23C illustrate a cross-sectional view of a semiconductor device having a backside via cut along the lines A-A′ according to an embodiment of the present disclosure.

FIG. 23D illustrate a cross-sectional view of a semiconductor device having a backside via cut along the lines B-B′ according to an embodiment of the present disclosure.

FIGS. 24-25 illustrate cross-sectional views of semiconductor devices having backside vias according to other embodiments of the present disclosure.

FIGS. 26A-26B is a flow chart of a method to form a semiconductor device having a backside via, in portion or in entirety, according to various aspects of the present disclosure.

FIGS. 27A-27B illustrate three-dimensional and top views of a semiconductor workpiece having lines A-A′ and B-B′ cut across source/drain regions of the workpiece.

FIGS. 28A-47A illustrate cross-sectional views of a semiconductor device cut along the lines A-A′ in FIGS. 27A-27B at intermediate stages of fabrication and processed in accordance with the method of FIGS. 26A-26B according to an embodiment of the present disclosure.

FIGS. 28B-29B, 32B-35B, and 39B-47B illustrate cross-sectional views of a semiconductor device cut along the lines B-B′ in FIGS. 27A-27B at intermediate stages of fabrication and processed in accordance with the method of FIGS. 26A-26B according to an embodiment of the present disclosure.

FIG. 47C illustrate a cross-sectional view of a semiconductor device having a backside via cut along the lines A-A′ according to an embodiment of the present disclosure.

FIG. 47D illustrate a cross-sectional view of a semiconductor device having a backside via cut along the lines B-B′ according to an embodiment of the present disclosure.

FIGS. 48-51 illustrate cross-sectional views of semiconductor devices having backside vias according to other embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower.” “above.” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” and the like, the term is intended to encompass numbers that are within a reasonable range including the number described, such as within +/−10% of the number described, or other values as understood by person skilled in the art. For example, the term “about 5 nm” may encompass the dimension range from 4.5 nm to 5.5 nm.

The present disclosure relates to semiconductor devices having backside vias, also referred to as backside contacts. For device shrinkage and reducing power consumption, certain power connection features such as vias are moved to the back side of the substrate. However, as device features scale down, spacing between metal gates and the adjacent source/drain features becomes tighter. As such, backside vias that connect to the source/drain features may get too close to the metal gates, causing current leakage issues between the gate and the backside vias. To prevent leakage and the possibility of shorting gate and source/drain connections, the present disclosure provides solutions for better insulation of backside vias from surrounding features. For example, the backside vias are formed deeper into the substrate for increased spacing between the backside vias and the metal gates. For another example, a backside dielectric cap is used as part of forming backside vias. And for another example, the backside vias are surrounded by an interlayer dielectric (ILD) layer.

To illustrate the various aspects of the present disclosure, methods of forming a semiconductor device are discussed below. Embodiments shown in the present disclosure are implemented with Gate-All-Around (GAA) field effect transistors (FETs), but the present disclosure is not limited thereto. GAA FETs refer to transistors having gate stacks (gate electrodes and gate dielectric layers) surrounding transistor channels, such as vertically-stacked gate-all-around horizontal nanowire or nanosheet MOSFET devices. Those of ordinary skill in the art should appreciate that they may readily use the present disclosure as a basis for designing or modifying other structures for carrying out the same purposes and/or achieving the same advantages of the embodiments introduced herein.

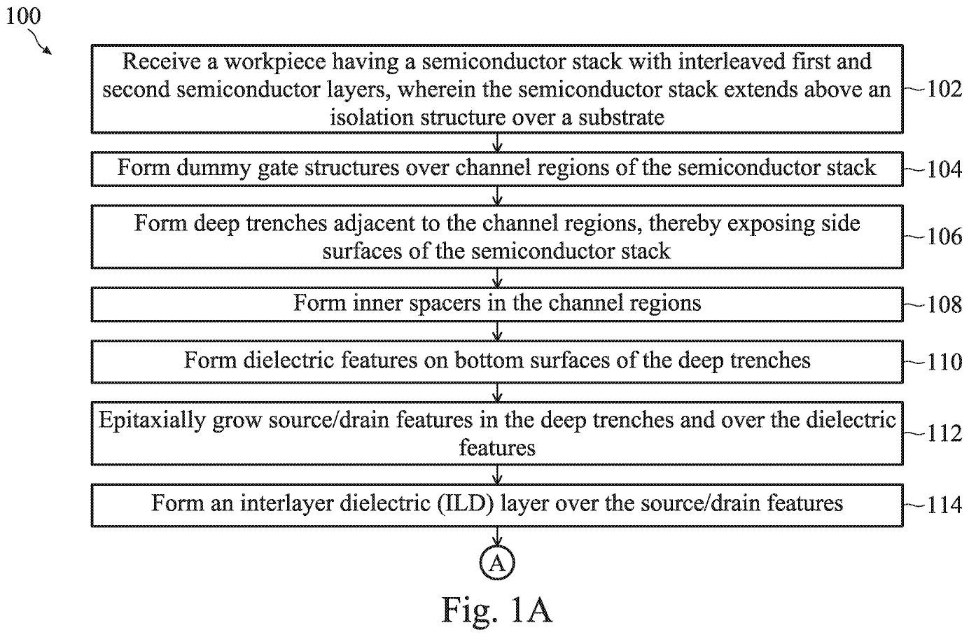

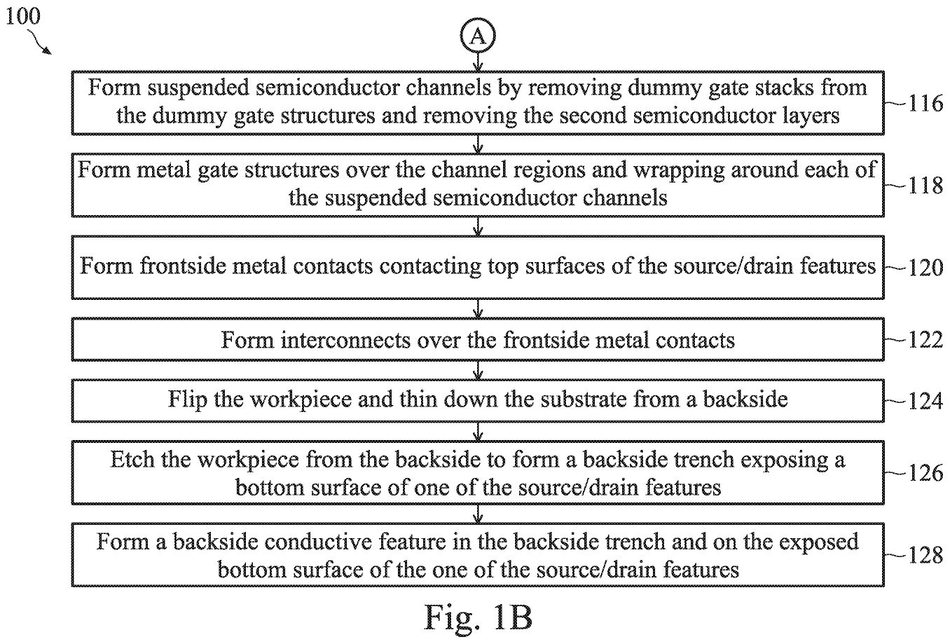

FIGS. 1A-1B illustrate a flow chart of a method 100 to form a semiconductor device having a backside via, in portion or in entirety, according to various aspects of the present disclosure. The method 100 is briefly described below. At operation 102, the method 100 receives or is provided with a workpiece that includes a semiconductor stack with interleaved first and second semiconductor layers. The semiconductor stack extends above an isolation structure over a substrate. At operation 104, the method 100 forms dummy gate structures (including dummy gate stacks and gate spacers) over channel regions of the semiconductor stack. The channel regions are defined by the regions underneath the dummy gate stacks. Adjacent to the channel regions are source/drain regions where source/drain features will be formed. At operation 106, the method 100 forms deep trenches in the source/drain regions (i.e., adjacent to the channel regions). The deep trenches expose side surfaces of the semiconductor stack. At operation 108, the method 100 forms inner spacers in the channel regions. At operation 110, the method 100 forms dielectric features on bottom surfaces of the deep trenches. At operation 112, the method 100 forms source/drain features in the deep trenches. At operation 114, the method 100 forms an interlayer dielectric (ILD) layer over the source/drain features. At operation 116, the method 100 forms suspended semiconductor channels by removing the dummy gate stacks from the dummy gate structures and removing the second semiconductor layers. At operation 118, the method 100 forms metal gate structures over the channel regions. The respective metal gate structures also wrap around each of the suspended semiconductor channels in respective channel regions. At operation 120, the method 100 forms frontside metal contacts over the source/drain features. At operation 122, the method 100 forms interconnects (or an interconnect layer having interconnect features) over the frontside contacts. At operation 124, the method 100 flips the workpiece and thins down the substrate from a backside. At operation 126, the method 100 etches the workpiece from the backside to form a backside trench exposing a bottom surface of one of the source/drain features. At operation 128, the method 100 forms a backside conductive feature (i.e., backside via or backside metal contact) in the backside trench and on the exposed bottom surface of the one of the source/drain features. The method 100 may perform further steps to complete fabrication of a semiconductor device. Additional processing is contemplated by the present disclosure. Additional operations can be provided before, during, and after method 100, and some of the operations described can be moved, replaced, or eliminated for additional embodiments of method 100.

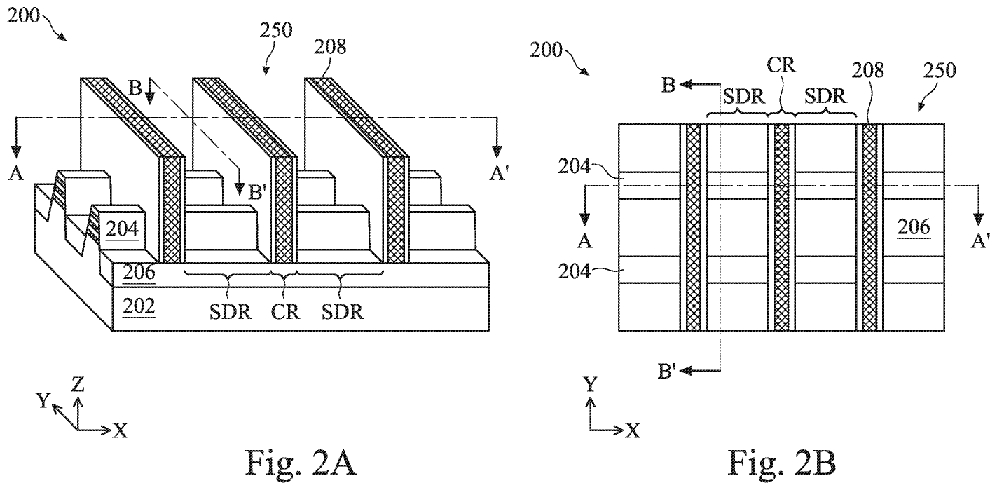

Method 100 is described below starting with FIGS. 2A-2B, which illustrate three-dimensional and top views of a semiconductor workpiece 250 having lines A-A′ and B-B′ cut across source/drain regions SDR in the x and y directions, respectively. The workpiece 250 shows a starting semiconductor device 200, which will be furthered processed according to embodiments of the present disclosure.

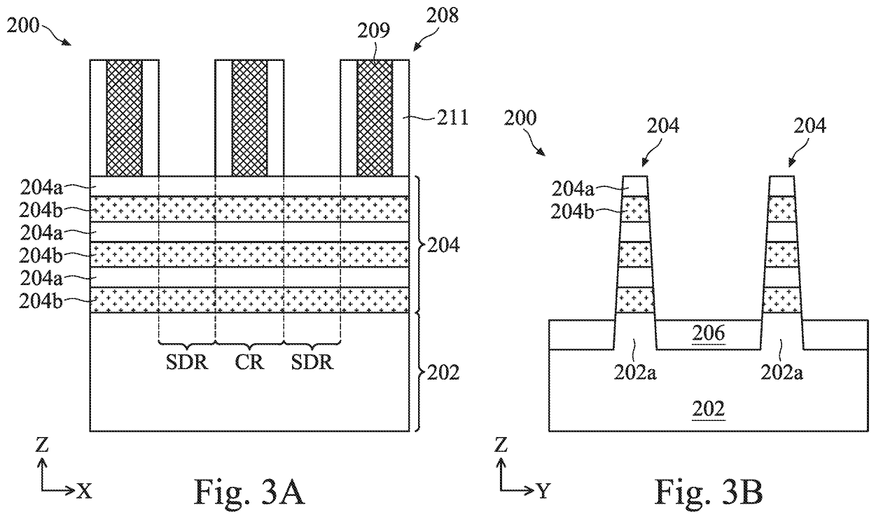

Method 100 is further described below in conjunction with FIGS. 3A-23A depicting cross-sectional views of the semiconductor device 200 in the x-z plane, and FIGS. 3B-4B, 10B-11B, and 15B-23B depicting cross-sectional views of the semiconductor device 200 in the y-z plane. These figures illustrate various views of the semiconductor device 200 at intermediate stages of fabrication and processed according to an embodiment of the present disclosure. These figures have been simplified for the sake of clarity to better understand the inventive concepts of the present disclosure. Additional features can be added in the device 200, and some of the features described below can be replaced, modified, or eliminated in other embodiments of the device 200.

The semiconductor device 200 may be a portion of an integrated circuit (IC) chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other suitable components, or combinations thereof. In some embodiments, the device is included in a non-volatile memory, such as a non-volatile random access memory (NVRAM), a flash memory, an electrically erasable programmable read only memory (EEPROM), an electrically programmable read-only memory (EPROM), other suitable memory type, or combinations thereof.

At operation 102, the method 100 receives a workpiece 250 of the semiconductor device 200, an embodiment of which is illustrated in FIGS. 2A-2B. The workpiece 250 may include a substrate 202 and a semiconductor stack 204 protruding from the substrate 202. The semiconductor stack 204 protrudes above an isolation structure 206 disposed over the substrate 202. The isolation structure 206 provides isolation between adjacent semiconductor stacks 204 and may be a shallow trench isolation (STI) layer. At operation 104, the method 100 forms dummy gate structures 208 over channel regions CR of the semiconductor stacks 204. The channel regions are defined by portions of the semiconductor stack 204 underneath the dummy gate structures 208. Adjacent to the channel regions are source drain regions SDR of the semiconductor stack 204. The semiconductor stacks 204 extend lengthwise in the x direction, and the dummy gate structures 208 extend lengthwise in the y direction. Note that forming dummy gate structures 208 is a separate step from forming semiconductor stacks 204. But for the sake of brevity. FIGS. 2A-2B show the received workpiece 250 already having dummy gate structures 208 formed.

Still referring to FIGS. 2A-2B, the respective A-A′ lines cuts along a semiconductor stack 204 in the x direction (lengthwise direction of the semiconductor stacks) across several dummy gate structures 208. The respective B-B′ lines cuts across source drain regions SDR of semiconductor stacks 204 in the y direction (lengthwise direction of the dummy gate structures 208) and across portions of the isolation structure 206 surrounding the semiconductor stacks 204. The lines A-A′ and B-B′ are chosen to illustrate cross-sectional views of various feature formations in the source/drain regions SDR.

FIGS. 3A-23A illustrate cross-sectional views of the semiconductor device 200 cut along the lines A-A′ at intermediate stages of fabrication and processed in accordance with the method of FIGS. 1A-1B. And FIGS. 3B-4B, 10B-11B, and 15B-23B illustrate cross-sectional views of the semiconductor device 200 cut along the lines B-B′ at intermediate stages of fabrication and processed in accordance with the method of FIGS. 1A-1B.

As shown in FIG. 3A, a semiconductor stack 204 is disposed over a substrate 202. The substrate 202 may be a silicon (Si) substrate, or a substrate having other semiconductor materials such as germanium (Ge), silicon carbide (SiC), silicon germanium (SiGe), or diamond. The semiconductor stack 204 may also be referred to as active regions. The semiconductor stack 204 includes interleaved first and second semiconductor layers 204a and 204b. The first semiconductor layers 204a have a different material composition than the second semiconductor layers 204b. For example, each of the first semiconductor layers 204a is made of silicon and each of the second semiconductor layers 204b is made of silicon germanium. The first semiconductor layers 204a may be of a same material composition as the substrate 202. The dummy gate structures 208 are disposed over the channel regions CR of the semiconductor stacks 204. Each of the dummy gate structures 208 includes a dummy gate stack 209 and gate spacers 211 over sidewalls of the dummy gate stack 209. The dummy gate stack 209 may be made of polysilicon and the gate spacers 211 may be made of silicon oxide, silicon nitride, silicon oxycarbide, silicon oxycarbonitride, silicon carbonitride, metal nitride, or a suitable dielectric material. The source drain regions SDR extend between adjacent dummy gate structures 208.

Now referring to FIG. 3B, each of the semiconductor stacks 204 extends above an isolation structure 206 over the substrate 202. The substrate 202 may include protruding portions 202a that protrude above a top surface of the isolation structure 206. And the semiconductor stacks 204 may extend from top surfaces of the protruding portions 202a. Each of the protruding portions 202a are interposed by the isolation structure 206. As such, the isolation structure 206 interfaces with a top surface of the substrate 202 and side surfaces of the protruding portions 202a. The isolation structure 206, which may be a shallow trench isolation (STI) layer, provides isolation between adjacent semiconductor stacks 204. In an example process, a dielectric material for the isolation structure 206 is deposited over the workpiece 250 using CVD, subatmospheric CVD (SACVD), flowable CVD, physical vapor deposition (PVD), spin-on coating, and/or other suitable process. Then the deposited dielectric material is planarized and recessed until the semiconductor stacks 204 rises above the isolation structure 206. The dielectric material for the isolation structure 206 may include silicon oxide, silicon oxynitride, fluorine-doped silicate glass (FSG), a low-k dielectric, combinations thereof, and/or other suitable materials.

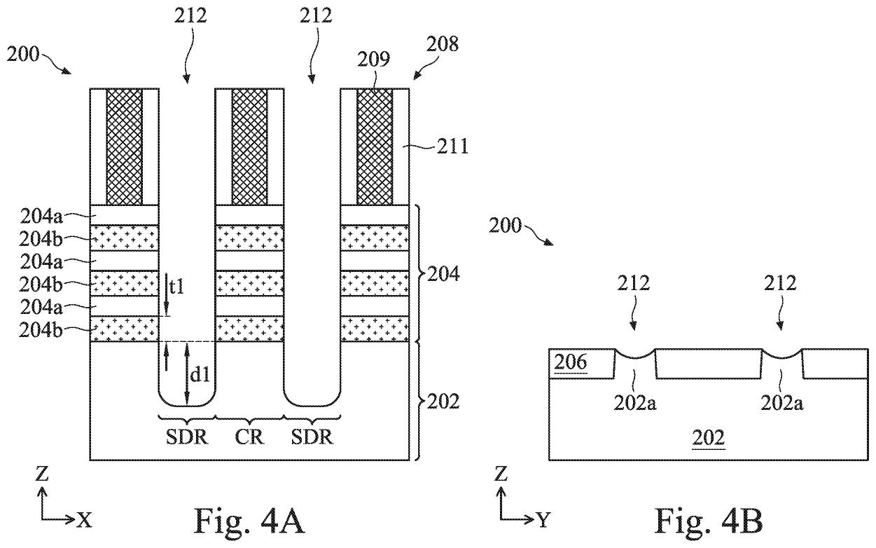

At operation 106, the method 100 forms deep trenches 212 in the source drain regions SDR adjacent to the channel regions CR of the device 200, an embodiment of which is illustrated in FIGS. 4A and 4B. The deep trenches 212 may also be referred to as source/drain trenches (recesses) and have sidewalls defined by the remaining portions of the semiconductor stacks 204. The deep trenches 212 may be formed by a dry etching process, a wet etching process, other suitable etching process, or combinations thereof. In some embodiments, the etching process is a multi-step etch process. For example, the etching process may include alternative etchants to separately and alternately remove semiconductor layers 204a and semiconductor layers 204b. In some embodiments, parameters of the etching process are configured to selectively etch semiconductor stacks 204 with minimal (to no) etching of dummy gate structures 208 (i.e., dummy gate stacks 209 and gate spacers 211). In some embodiments, a lithography process is performed to form a patterned mask layer that covers dummy gate structures 208 and/or portions of the isolation structures 206, and the etching process uses the patterned mask layer as an etch mask when forming the deep trenches 212.

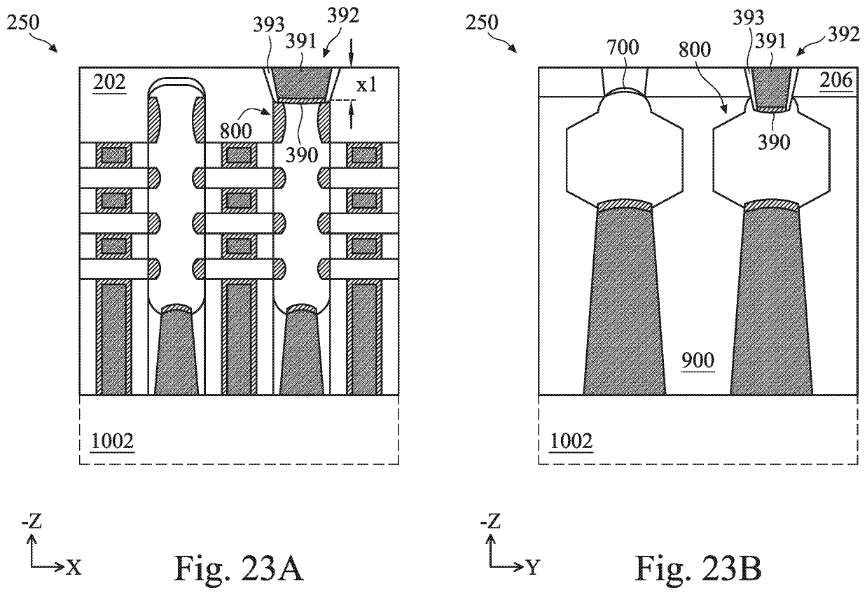

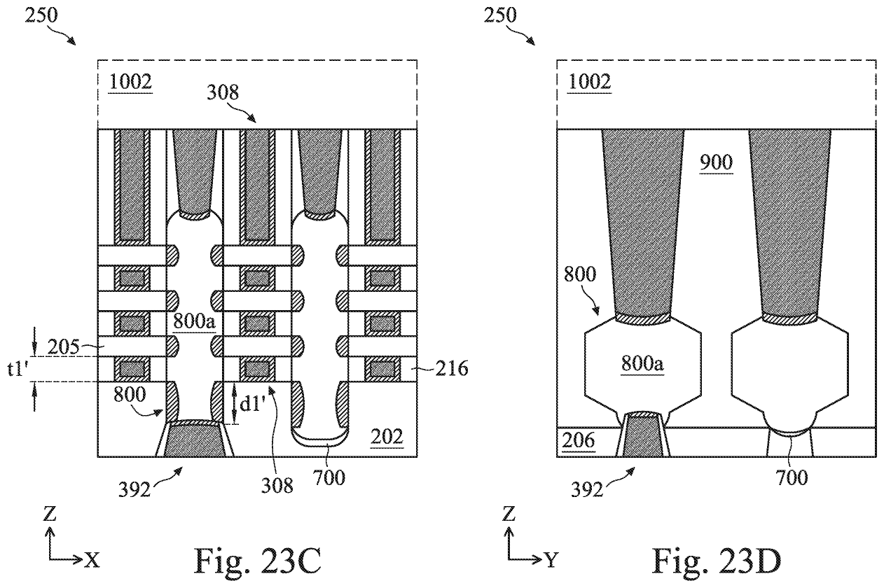

Referring to FIG. 4A, the deep trenches 212 extend into the substrate 202 past the bottommost semiconductor layers 204b of the semiconductor stacks 204. As shown, a distance d1 represents an etch distance between the bottommost semiconductor layer 204b and the bottommost surface of the deep trenches 212. A ratio between the distance d1 to a thickness t1 of one of the first or second semiconductor layers 204a or 204b may be in a range of 2 to 5. The distance d1 may be in a range between 20 to 50 nm, and the thickness t1 may be in a range of 5-15 nm. As will be explained in more detail with respect to FIG. 23C, a sufficient distance d1 is necessary to ensure proper spacing and insulation between a later-formed backside via and a later-formed bottommost portion of a gate structure. In some embodiments, the etch distance d1 must also account for a later-formed dielectric feature in the deep trenches 212, which will be etched away in later process steps. However, excessive spacing, such as a ratio of d1 to t1 greater than 5 is also not desirable because this will unnecessarily enlarge device footprint. As long as the benefit of gate to backside via isolation is achieved, any excessive spacing (e.g., d1/t1 greater than 5) will only incur additional cost and space. As such, the etch distance d1 should not be too shallow or too deep. Referring to FIG. 4B, the deep trenches 212 may extend below a top surface of the isolation structure 206 but not below a bottom surface of the isolation structure 206.

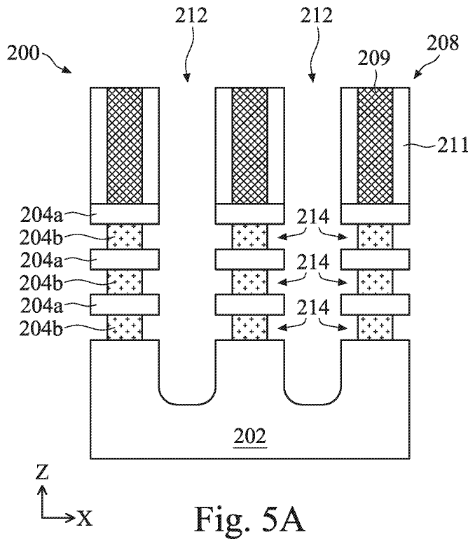

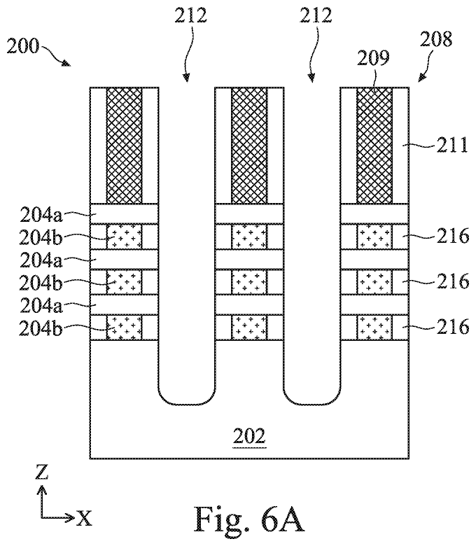

At operation 108, the method 100 forms inner spacers 216 in the channel regions CR along sidewalls of the semiconductor layers 204b by any suitable process. FIGS. 5A and 6A illustrate example process steps of forming the inner spacers 216. First, as shown in FIG. 5A, a side etch process is performed to selectively etch sidewalls of the second semiconductor layers 204b without etching (or substantially etching) the first semiconductor layers 204a. In other words, the side etch process is configured to laterally etch (e.g., along the x direction) semiconductor layers 204b, thereby reducing a length of semiconductor layers 204b along the x direction. The side etch process is a dry etching process, a wet etching process, other suitable etching process, or combinations thereof. After the side etch process is performed, air gaps 214 are formed under each of the first semiconductor layers 204a. Then, as shown in FIG. 6A, inner spacers 216 are formed in each of the air gaps 214. The inner spacers 216 are disposed directly below the gate spacers 211, and they may be substantially vertically aligned with the gate spacers 211 along the z direction.

The inner spacers 216 may be formed by a spacer deposition process and a spacer etching process. For example, a spacer deposition process is performed to form a spacer layer over the dummy gate structures 208 and over features defining the deep trenches 212 (e.g., semiconductor layers 204a, semiconductor layers 204b, and substrate 202 in FIG. 5A). The spacer deposition process may include processes such as CVD, PVD, ALD, HDPCVD, MOCVD, RPCVD, PECVD, LPCVD, ALCVD, APCVD, plating, other suitable methods, or combinations thereof. The spacer layer partially (and, in some embodiments, completely) fills the deep trenches 212. The spacer deposition process is configured to ensure that the spacer layer fills the air gaps 214 between semiconductor layers 204a and between semiconductor layers 204a and substrate 202 under gate spacers 211. A spacer etching process is then performed that selectively etches the spacer layer to form inner spacers 216 as depicted in FIG. 6A with minimal (to no) etching of semiconductor layers 204a, dummy gate stacks 209, and gate spacers 211. The spacer layer (and thus inner spacers 216) includes a material that is different than a material of semiconductor layers 204a and a material of gate spacers 211 to achieve desired etching selectivity during the gate spacer etching process. In some embodiments, the spacer layer includes a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the spacer layer includes a low-k dielectric material.

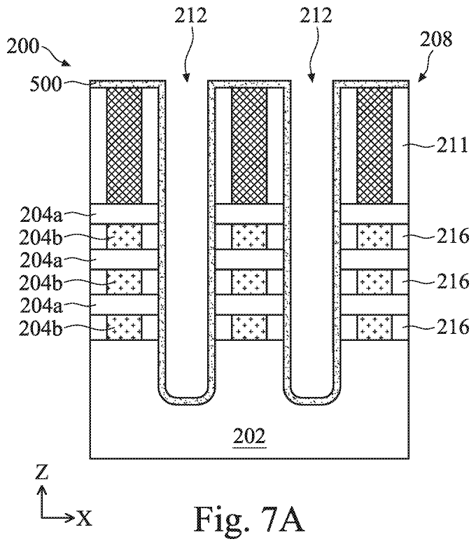

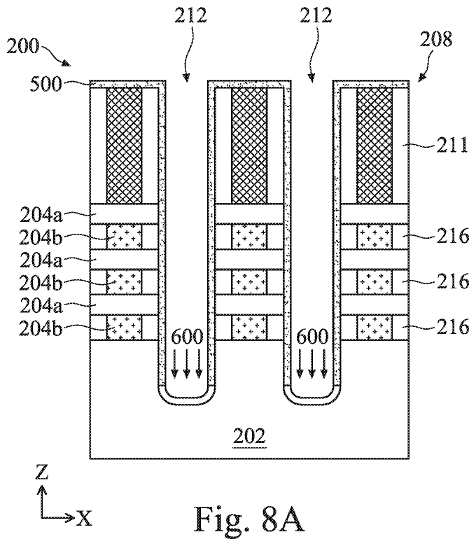

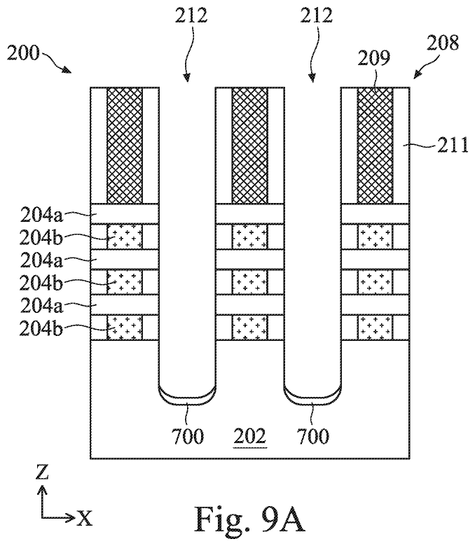

At operation 110, the method 100 forms dielectric features 700 on bottom surfaces of the deep trenches 212. FIGS. 7A-9A illustrate example process steps of forming the dielectric features 700. First, referring to FIG. 7A, a dielectric layer 500 is conformally deposited into the deep trenches 212 and over the dummy gate structures 208. The dielectric layer 500 may be deposited by an ALD process and the dielectric layer 500 is disposed along bottom and side surfaces of the deep trenches 212. The dielectric layer 500 may include silicon nitride. Second, referring to FIG. 8A, a directional plasma treatment 600 is performed on a bottom horizontal surface of the dielectric layer 500 in the deep trenches 212. The directional plasma treatment 600 may include a nitrogen plasma surface treatment. The treated bottom horizontal surface of the dielectric layer 500 may include more nitrogen than the untreated sidewall portions of the dielectric layer 500. Third, referring to FIG. 9A, the untreated dielectric layer 500 on sidewalls of the deep trenches 212 is selectively etched away. This may be done by a wet etch sidewall removal process, which may be an isotropic process using HF. As such, what remains of the dielectric layer 500 are dielectric features 700 that only cover bottom surfaces of the deep trenches 212. The dielectric features 700 may have a thickness of 2 to 5 nm in the z direction. The dielectric features 700 may also be referred to as dielectric caps or capping layers. The advantages of such dielectric caps will be described in more detail with respect to FIGS. 23C-23D.

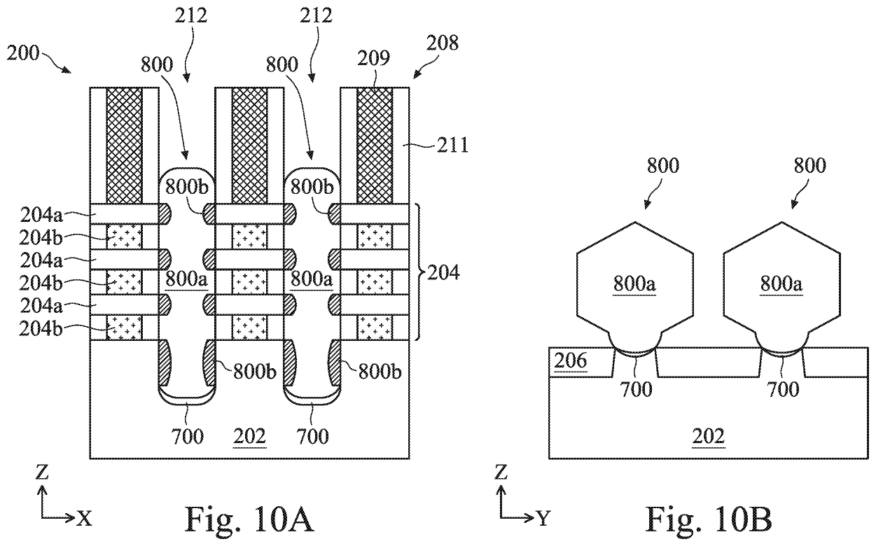

At operation 112, the method 100 epitaxially grows source/drain features 800 in the deep trenches 212 and over the dielectric features 700, an embodiment of which is illustrated in FIGS. 10A and 10B. The source/drain features 800 may include n-type source/drain features that correspond with n-type GAA transistor regions or p-type source/drain features that correspond with p-type GAA transistor regions. The source/drain features 800 may be formed by an epitaxy process using CVD deposition techniques (for example, VPE and/or UHV-CVD), molecular beam epitaxy, other suitable epitaxial growth processes, or combinations thereof. The epitaxy process can use gaseous and/or liquid precursors, which interact with the composition of substrate 202 and/or semiconductor stacks 204 (in particular, semiconductor layers 204a). Epitaxial source/drain features 800 are doped with n-type dopants and/or p-type dopants. In some embodiments, for the n-type GAA transistors, epitaxial source/drain features 800 include silicon and can be doped with carbon, phosphorous, arsenic, other n-type dopant, or combinations thereof (for example, forming Si:C epitaxial source/drain features, Si:P epitaxial source/drain features, or Si:C:P epitaxial source/drain features). In some embodiments, for the p-type GAA transistors, epitaxial source/drain features 800 include silicon germanium or germanium and can be doped with boron, other p-type dopant, or combinations thereof (for example, forming Si:Ge:B epitaxial source/drain features).

In some embodiments, epitaxial source/drain features 800 include materials and/or dopants that achieve desired tensile stress and/or compressive stress in respective channel regions CR. In some embodiments, epitaxial source/drain features 800 are doped during deposition by adding impurities to a source material of the epitaxy process (i.e., in-situ). In some embodiments, epitaxial source/drain features 800 are doped by an ion implantation process subsequent to a deposition process. In some embodiments, annealing processes (e.g., rapid thermal annealing (RTA) and/or laser annealing) are performed to activate dopants in epitaxial source/drain features 800 and/or other source/drain regions (for example, heavily doped source/drain regions and/or lightly doped source/drain (LDD) regions). In some embodiments, epitaxial source/drain features 800 are formed in separate processing sequences that include, for example, masking p-type GAA transistor regions when forming epitaxial source/drain features 800 in n-type GAA transistor regions and masking n-type GAA transistor regions when forming epitaxial source/drain features 800 in p-type GAA transistor regions.

In some embodiments, as shown in FIG. 10A, epitaxial source/drain features 800 are formed to include more than one epitaxial layer. Specifically, each of the source/drain features 800 includes an inner heavily doped layer 800a and an outer lightly doped layer (or layers) 800b. In one embodiment, the outer lightly doped layer 800b is first epitaxially grown in the deep trenches 212 from side surfaces of the semiconductor layers 204a and the substrate 202. Then, the inner heavily doped layer 800a is epitaxially grown from the outer lightly doped layer 800b to fill the deep trenches 212. The outer lightly doped layers 800b may have a thickness of 2 to 5 nm in the x direction, and the inner heavily doped layers 800a fill the rest of the spaces in the deep trenches 212. Note that the dielectric features 700 may directly interface the heavily doped layers 800a. The source/drain features 800 may grow to a height above the topmost first semiconductor layers 204a and between gate spacers 211 of different dummy gate structures 208. As shown in FIG. 10B, the source/drain features 800 are grown over the isolation structure 206 and over the dielectric features 700. Note that in this cross section, only the heavily doped layer 800a is present.

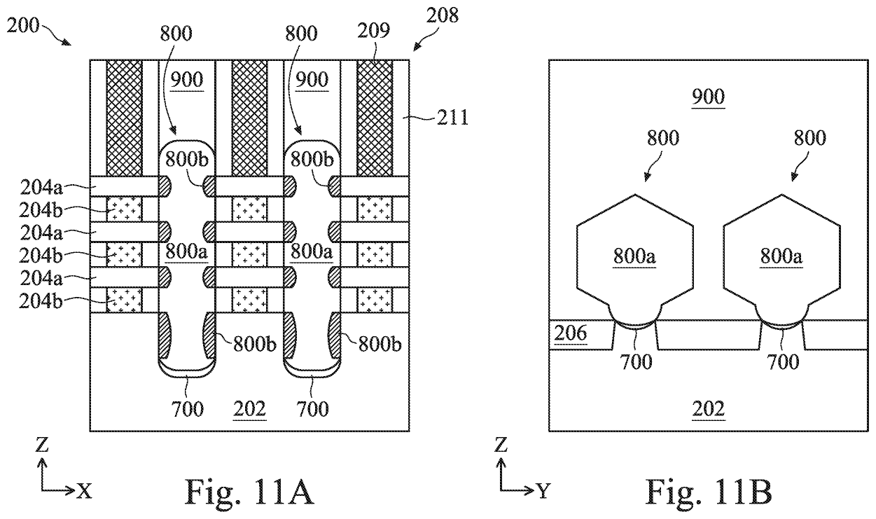

At operation 114, the method 100 forms an interlayer dielectric (ILD) layer 900 over the source/drain features 800 and over the isolation structure 206, an embodiment of which is illustrated in FIGS. 11A and 11B. As shown in FIG. 11A, the ILD layer 900 also fills the space between adjacent dummy gate structures 208. The ILD layer 900 may be formed by a deposition process (such as CVD, PVD, ALD, HDPCVD, MOCVD, RPCVD, PECVD, LPCVD, ALCVD, APCVD, plating, other suitable methods, or combinations thereof). In some embodiments, ILD layer 900 is formed by a flowable CVD (FCVD) process that includes, for example, depositing a flowable material (such as a liquid compound) over the device 200 and converting the flowable material to a solid material by a suitable technique, such as thermal annealing and/or ultraviolet radiation treating. The ILD layer 900 includes a dielectric material including, for example, silicon oxide, silicon nitride, silicon oxynitride, TEOS formed oxide, PSG, BPSG, low-k dielectric material, other suitable dielectric material, or combinations thereof. Exemplary low-k dielectric materials include FSG, carbon doped silicon oxide, Black Diamond® (Applied Materials of Santa Clara, California), Xerogel, Aerogel, amorphous fluorinated carbon, Parylene, BCB, SiLK (Dow Chemical, Midland, Michigan), polyimide, other low-k dielectric material, or combinations thereof. In the depicted embodiment, ILD layer 900 is a dielectric layer that includes a low-k dielectric material (generally referred to as a low-k dielectric layer). ILD layer 900 can include a multilayer structure having multiple dielectric materials. In some embodiments, a contact etch-stop layer (CESL) is disposed between ILD layer 900 and the isolation structure 206, epitaxial source/drain features 800, and gate spacers 211. The CESL includes a material different than ILD layer 900, such as a dielectric material that is different than the dielectric material of ILD layer 900. For example, where ILD layer 900 includes a low-k dielectric material, the CESL includes silicon and nitrogen, such as silicon nitride or silicon oxynitride. Subsequent to the deposition of ILD layer 900 and/or the CESL, a CMP process and/or other planarization process may be performed until reaching (exposing) a top portion (or top surface) of dummy gate stacks 209.

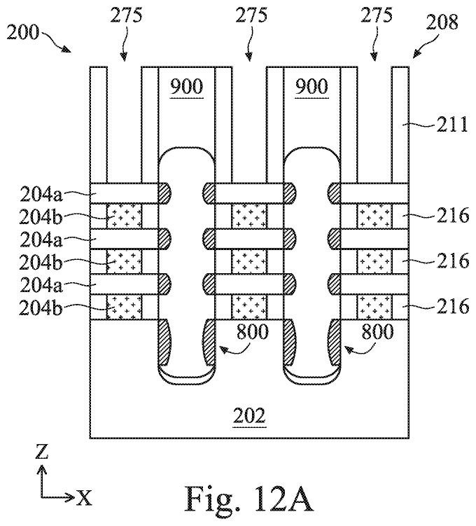

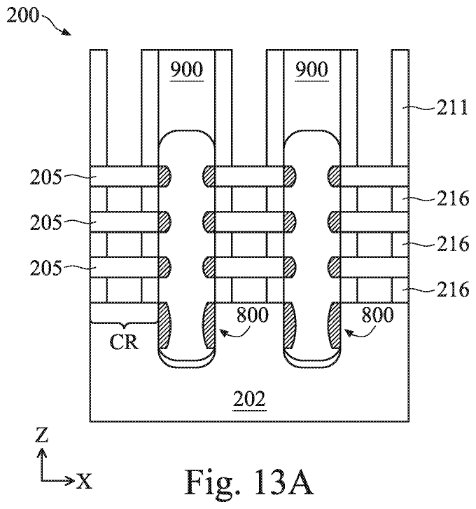

At operation 116, the method 100 forms suspended semiconductor channels 205 by removing the dummy gate stacks 209 from the dummy gate structures 208 and removing the second semiconductor layers 204b. FIGS. 12A and 13A illustrate example process steps involved in operation 116.

First, as shown in FIG. 12A, the dummy gate stacks 209 are removed by a suitable etching process, thereby resulting in gate trenches 275 and exposing the semiconductor stacks 204. The etching process is designed with etchant to selectively remove the dummy gate stacks 209. In the depicted embodiment, an etching process completely removes dummy gate stacks 209 to expose surfaces of the semiconductor layers 204a and semiconductor layers 204b in the x-z plane. The etching process is a dry etching process, a wet etching process, other suitable etching process, or combinations thereof. In some embodiments, the etching process is a multi-step etch process. For example, the etching process may include alternative etchants to separately remove various layers of dummy gate stacks 209, such as the dummy gate electrode layers, the dummy gate dielectric layers, and/or the hard mask layers. In some embodiments, the etching process is configured to selectively etch dummy gate stacks 245 with minimal (to no) etching of other features of the device 200, such as ILD layer 900, gate spacers 211, semiconductor layers 204a, and semiconductor layers 204b. In some embodiments, a lithography process is performed to form a patterned mask layer that covers ILD layer 900 and/or gate spacers 211, and the etching process uses the patterned mask layer as an etch mask.

Second, as shown in FIG. 13A, the second semiconductor layers 204b (exposed by the gate trenches 275) are selectively removed from the channel regions CR, forming suspended semiconductor channels 205. In other words, what remains of the semiconductor layers 204a now become suspended semiconductor channels 205. In the depicted embodiment, an etching process selectively etches semiconductor layers 204b with minimal (to no) etching of semiconductor layers 204a and, in some embodiments, minimal (to no) etching of gate spacers 211 and/or inner spacers 216. Various etching parameters can be tuned to achieve selective etching of semiconductor layers 204b, such as etchant composition, etching temperature, etching solution concentration, etching time, etching pressure, source power, RF bias voltage, RF bias power, etchant flow rate, other suitable etching parameters, or combinations thereof. For example, an etchant is selected for the etching process that etches the material of semiconductor layers 204b (in the depicted embodiment, silicon germanium) at a higher rate than the material of semiconductor layers 204a (in the depicted embodiment, silicon) (i.e., the etchant has a high etch selectivity with respect to the material of semiconductor layers 204b). The etching process is a dry etching process, a wet etching process, other suitable etching process, or combinations thereof. In some embodiments, a dry etching process (such as an RIE process) utilizes a fluorine-containing gas (for example, SF6) to selectively etch semiconductor layers 204b. In some embodiments, a ratio of the fluorine-containing gas to an oxygen-containing gas (for example, O2), an etching temperature, and/or an RF power may be tuned to selectively etch silicon germanium (or silicon). In some embodiments, a wet etching process utilizes an etching solution that includes ammonium hydroxide (NH4OH) and water (H2O) to selectively etch semiconductor layers 204b. In some embodiments, a chemical vapor phase etching process using hydrochloric acid (HCl) to selectively etch semiconductor layers 204b.

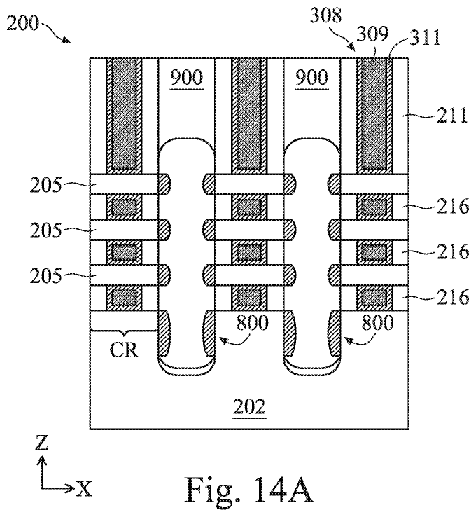

At operation 118, the method 100 forms metal gate structures 308 (may also be referred to as gate stacks) over the channel regions CR and wrapping around each of the suspended semiconductor channels 205, an embodiment of which is illustrated in FIG. 14A. Each of the gate structures 308 includes a gate dielectric layer 311 and a gate electrode 309 disposed on the gate dielectric layer 311. In some embodiments, the gate dielectric layer 311 includes an interfacial layer and a high-k dielectric layer disposed on the interfacial layer. The gate electrode 309 may include one or more conductive materials, such as a capping layer, a work function metal layer, a blocking layer, a metal fill layer, and/or other proper conductive material layers. The work function layers (if present) may be same or different and may be an n-type work function layer or a p-type work function layer, depending on the types of the corresponding GAA transistors. The gate dielectric layer 311 includes a high-k dielectric material, such as materials having a dielectric constant greater than silicon oxide (k≈3.9). The gate electrodes 309 may be formed by a CVD process or a PVD process that deposits a metal fill layer that fills remaining portions of the gate trenches 275 and over the gate dielectric layers 311. The metal fill layer includes a suitable conductive material, such as Al, W, and/or Cu. The metal fill layer may additionally or collectively include other metals, metal oxides, metal nitrides, other suitable materials, or combinations thereof. Alternatively, the metal fill layer is formed using another suitable deposition process, such as ALD, CVD, PVD, HDPCVD, MOCVD, RPCVD, PECVD, LPCVD, ALCVD, APCVD, spin coating, plating, other deposition process, or combinations thereof.

A planarization process is performed to remove excess gate materials from the semiconductor device 200. For example, a CMP process is performed until a top surface of the ILD layer 900 is reached (exposed) so that top surfaces of the metal gate structures 308 are substantially planar with a top surface of ILD layer 900 after the CMP process. Accordingly, the semiconductor device 200 now forms GAA transistors having gate structures 308 wrapping respective channel layers 205 (now no longer suspended), where the gate structures 308 are disposed between respective channel layers 205 along the z direction and between respective epitaxial source/drain features 800 along the x direction. Further, the metal gate structures 308 are separated from the source/drain features 800 by the gate spacers 211 and the inner spacers 216.

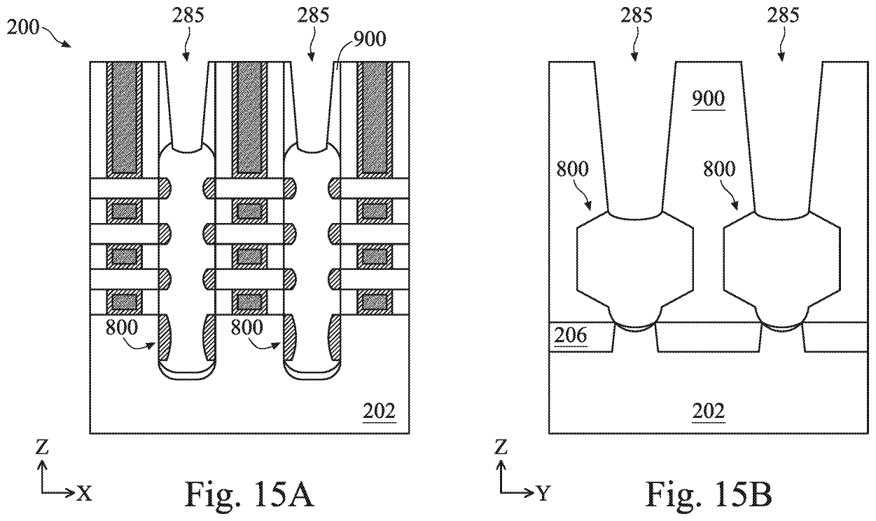

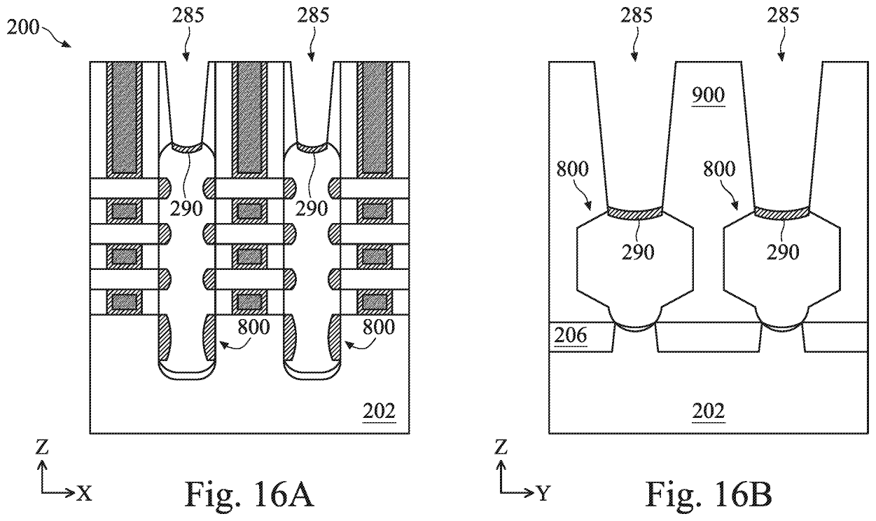

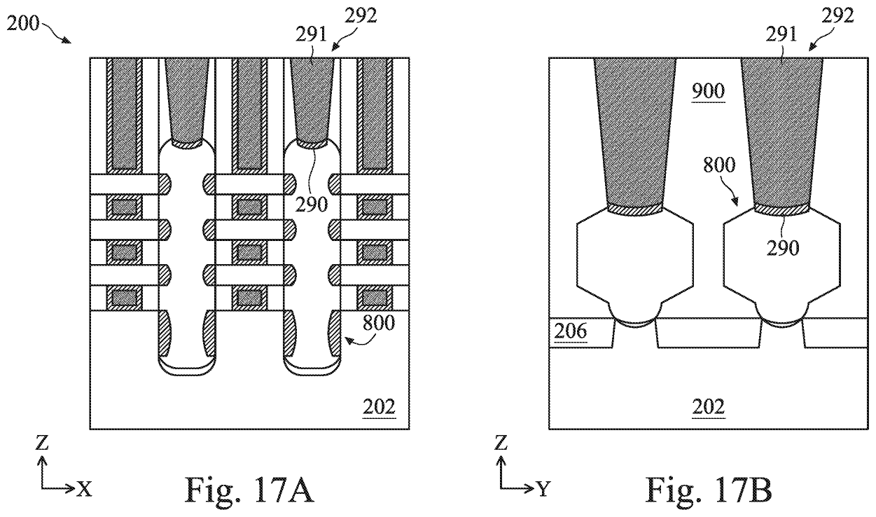

At operation 120, the method 100 forms frontside metal contacts 292 over the source/drain features 800. FIGS. 15A-17A and FIGS. 15B-17B illustrate example process steps of forming the frontside metal contacts 292. First, as shown in FIGS. 15A and 15B, frontside trenches 285 are formed through the ILD layer 900 to expose top surfaces of the source/drain epitaxial features 800. The trenches may be formed by any suitable etching process. In some embodiments, the frontside trenches 285 extend into the source/drain features 800 by a depth so that the source/drain features 800 have a dipped top surface. The extra extension is to ensure there is proper surface contact area for subsequent metal contact features. Second, metal contact features are deposited into the frontside trenches 285. The metal contact features include silicide features 290 (FIGS. 16A and 16B) and metal fill layers 291 (FIGS. 17A and 17B) over the silicide features to collectively form frontside metal contacts 292 (FIGS. 15A and 15B). The silicide features 290 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds. The metal fill layer 291 over the silicide features 290 may include titanium (Ti), ruthenium (Ru), copper (Cu), nickel (Ni), cobalt (Co), tungsten (W), tantalum (Ta), or molybdenum (Mo). Forming the frontside metal contacts 292 may include a CMP process to remove excess metal. The frontside metal contacts 292 may also be referred to as frontside vias, which may connect to additional frontside metal lines or traces.

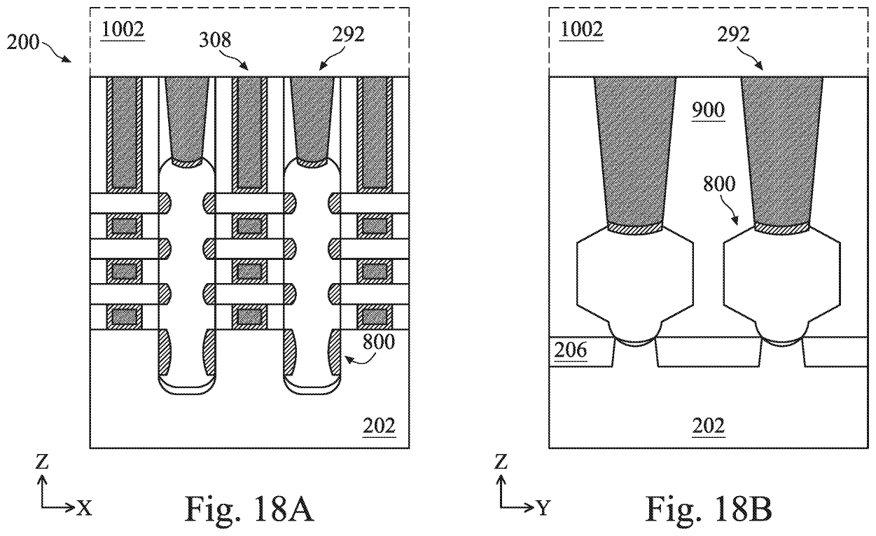

At operation 122, the method 100 forms interconnects (or an interconnect layer) 1002 over the frontside metal contacts 292 and over the metal gate structures 308, indicated by the dashed boxes in FIGS. 18A and 18B. The interconnect layer 1002 includes features that electrically couple various devices (for example, p-type GAA transistors and/or n-type GAA transistors of the device 200, transistors, resistors, capacitors, and/or inductors) and/or components (for example, gate structures and/or epitaxial source/drain features of p-type GAA transistors and/or n-type GAA transistors), such that the various devices and/or components can operate as specified by design requirements of the device 200. The interconnect layer 1002 includes a combination of dielectric layers and electrically conductive layers (e.g., metal layers) configured to form various interconnect structures. The conductive layers are configured to form vertical interconnect features, such as device-level contacts and/or vias, and/or horizontal interconnect features, such as conductive lines. Vertical interconnect features typically connect horizontal interconnect features in different layers (or different planes) of the interconnect layer. During operation, the interconnect layer 1002 is configured to route signals between the devices and/or the components of the device 200 and/or distribute signals (for example, clock signals, voltage signals, and/or ground signals) to the devices and/or the components of the device 200.

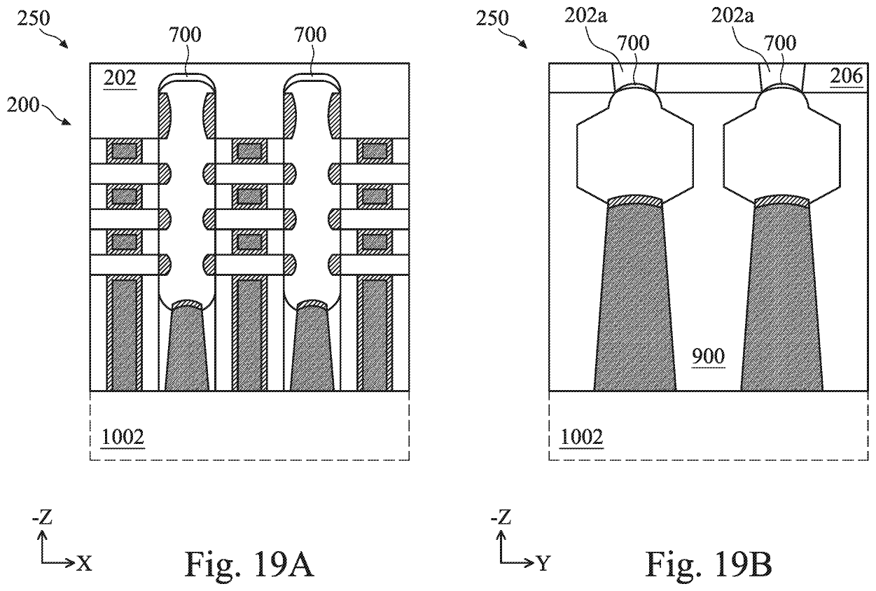

At operation 124, the method 100 flips the workpiece 250 of the semiconductor device 200 such that the backside of the substrate 202 is facing up, an embodiment of which is illustrated in FIGS. 19A and 19B. To keep orientation labels consistent, due to the flip, the axis facing vertically up is now shown as the −Z direction. After flipping the workpiece 250, the operation 124 may include a CMP process to thin down the substrate 202. After the thin down, as shown in FIG. 19B, the isolation structure 206 may be exposed from the backside such that it is coplanar with protruding portions 202a of the substrate 202. In some embodiments, the thinning down of the substrate 202 includes thinning down the isolation structure 206 from the backside. Note that the thinning down does not expose the dielectric features 700. In further embodiments (not shown), the backside substrate 202 is removed by a silicon removal process, followed by a silicon oxide deposition process. As such, the substrate 202 may be replaced by a silicon oxide layer (also referred to as a backside ILD layer). For example, a selective wet etching process targets the substrate 202 without etching other surrounding features, then a silicon oxide deposition (or silicon nitride plus silicon oxide bi-layer) process is performed followed by a CMP process.

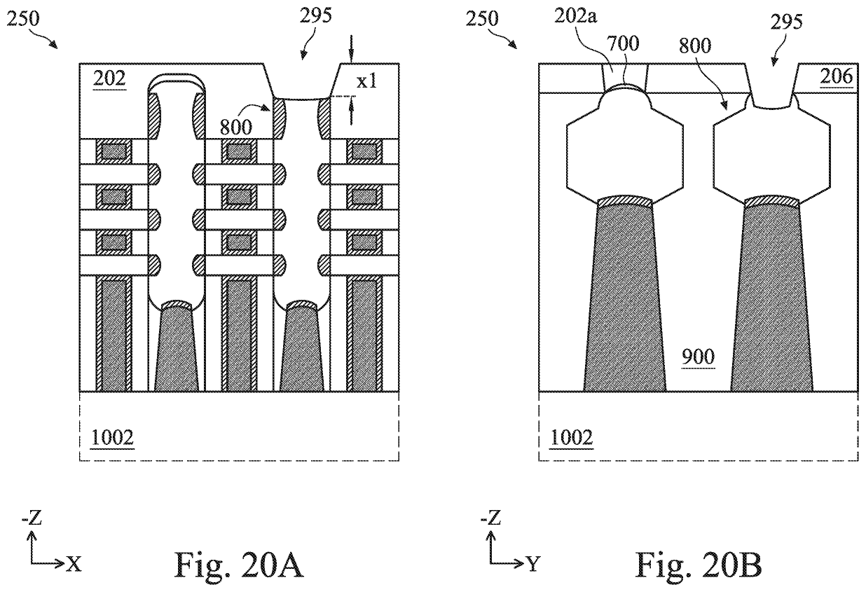

At operation 126, the method 100 etches the workpiece 250 from the backside to form a backside trench 295 exposing a bottom surface of one of the source/drain features 800, an embodiment of which is illustrated in FIGS. 20A and 20B. The backside trench 295 may be formed by an etching process similar to how the frontside trenches 285 are formed. As shown in FIG. 20A, the backside trench 295 is formed by etching through the thinned down substrate 202 and one of the dielectric features 700 to expose the heavily doped layer 800a of the one of the source/drain features 800. Further, as shown in FIG. 20B, the backside trench 295 is formed by etching through a protruding portion 202a of the substrate 202 and the isolation structure 206.

At operation 128, the method 100 forms a backside conductive feature 392 (i.e., backside via) in the backside trench 295 and on the exposed bottom surface of the one of the source/drain features 800, an embodiment of which is illustrated in FIGS. 23A and 23B.

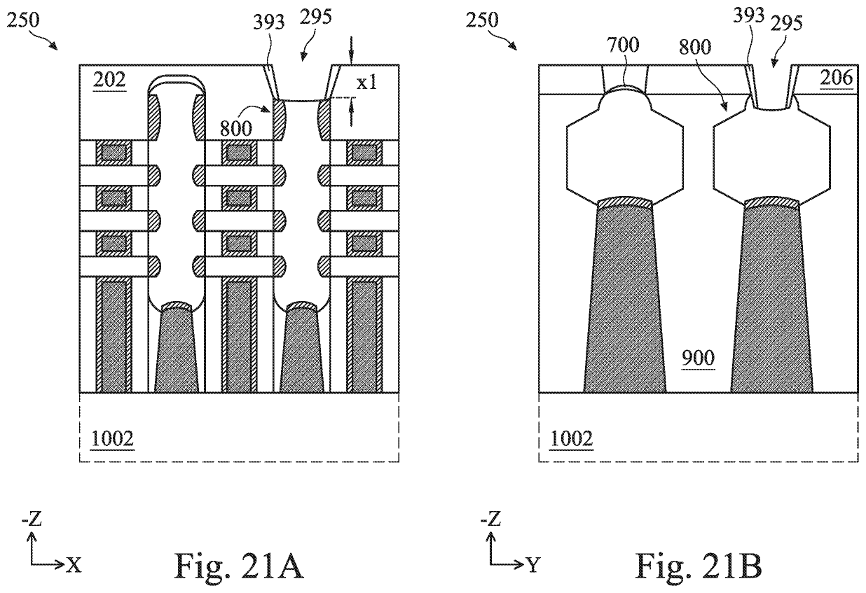

Referring now to FIGS. 21A and 21B, in some embodiments, backside barrier layers 393 are first formed along side walls of the backside trench 295 before forming the backside conductive feature 392. The barrier layers 393 is a dielectric barrier layer formed by a suitable procedure that includes deposition and anisotropic etch (e.g., plasma etch) to remove the deposited barrier layer on bottom surface of the trenches. The barrier layer may comprise silicon nitride, silicon oxynitride, other suitable dielectric material or a combination thereof.

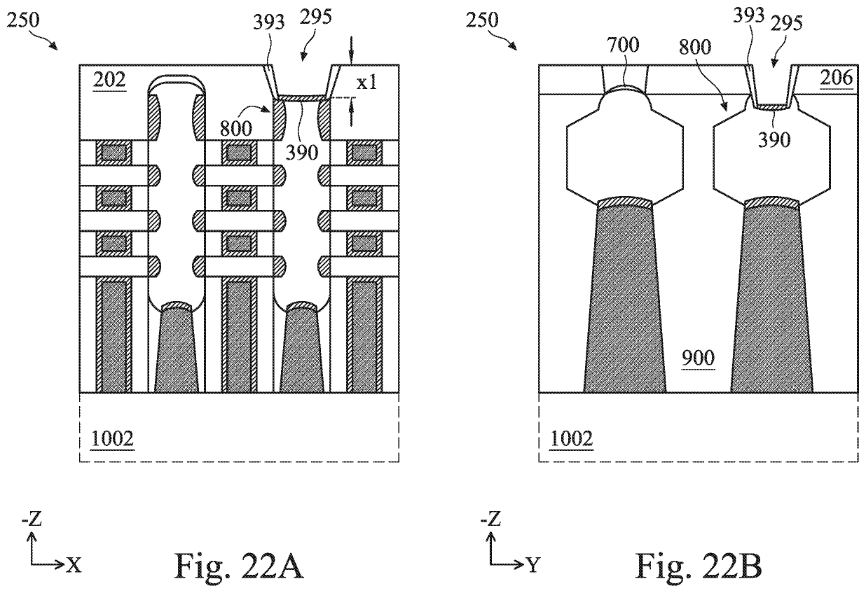

Referring to FIGS. 23A and 23B, backside metal contact features are then deposited into the trenches 295. The backside metal contact features include backside silicide features 390 (FIGS. 22A and 22B) and backside metal fill layers 391 (FIGS. 23A and 23B) to collectively form the backside metal contact 392. The backside silicide features 390 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds. The backside metal fill layer 391 over the silicide features 290 may include titanium (Ti), ruthenium (Ru), copper (Cu), nickel (Ni), cobalt (Co), tungsten (W), tantalum (Ta), or molybdenum (Mo). Forming the backside metal contact 392 may include a CMP process to remove excess metal. The backside metal contact 392 may also be referred to as a backside via, which may connect to additional backside metal lines or traces.

Referring now to FIGS. 23C and 23D, the workpiece 250 is flipped back to the x-z and y-z axis for purposes of illustration and describing relevant features. As shown, the backside metal contact 392 (or backside via) is vertically distanced from the metal gate structure 308 by a distance d1′. The distance d1′ is smaller than the etch distance d1 (see FIG. 4A) due to the dielectric feature 700 being etched away to expose the bottom of the source/drain feature 800. Specifically, the distance d1′ is a spacing between the bottommost gate portion of the metal gate structure 308 and the topmost surface of the backside metal contact 392. The bottommost gate portion of the metal gate structure 308 is below the bottommost channel layer 205 and above a top surface of the substrate 202. A ratio between the distance d1′ to a thickness t1′ is in a range of 1 to 3. The thickness t1′ is similar to the thickness t1 (see FIG. 4A), which may correspond in FIG. 23C to a thickness of the channel layers 205, the inner spacers 216, or the gate portions of the metal gate structure 308 between the channel layers 205. The distance d1′ may be in a range between 5 to 30 nm, and the thickness t1′ may be in a range of 5-15 nm. However, d1′ must be at least equal to or greater than t1′ to ensure the minimum ratio of d1′ to t1′. For example, if the thickness t1′ of the inner spacers 216 or channel layers 205 is to be 5 nm, the distance d1′ must also be at least 5 nm. This is because a sufficient distance d1′ is necessary to ensure proper spacing and insulation between the backside via 392 and the bottommost portion of the metal gate structure. The extra spacing prevents unwanted current leakage and possibility of shorting between gate and source/drain features. However, excessive spacing, such as a ratio of d1′ to t1′ greater than 3 is also not desirable because this will unnecessarily enlarge device footprint. As long as the benefit of gate to backside via isolation is achieved, any excessive spacing (e.g., d1/t1 greater than 3) will only incur additional cost and space. Note that in the y-z plane, a top surface of the backside via 392 may extend into the heavily doped layer 800a of the source/drain feature 800, such that the top surface of the backside via 392 is above the top surface of the isolation structure 206.

Still referring to FIGS. 23C and 23D, one of the source/drain features 800 is connected to a backside via 392 and another one of the source/drain features 800 is not. For source/drain features 800 not connected to backside vias 392, the dielectric cap 700 provides proper insulation to prevent stray conductance between those source/drain features 800 and other metal connections on the backside. Another advantage of the dielectric caps 700 is that it acts as an etch stop layer for proper etch height when forming backside trenches 295 and backside vias 392. Since the distance between the backside vias 392 and the metal gate structures 308 is sensitive, without the dielectric caps 700, there would be difficulty controlling the distance d1′ and undesirable over-etching may occur. With the dielectric caps 700, the proper distance d1′ can be controlled to ensure the benefits of proper isolation between the metal gate structures 308 and the backside vias 392.

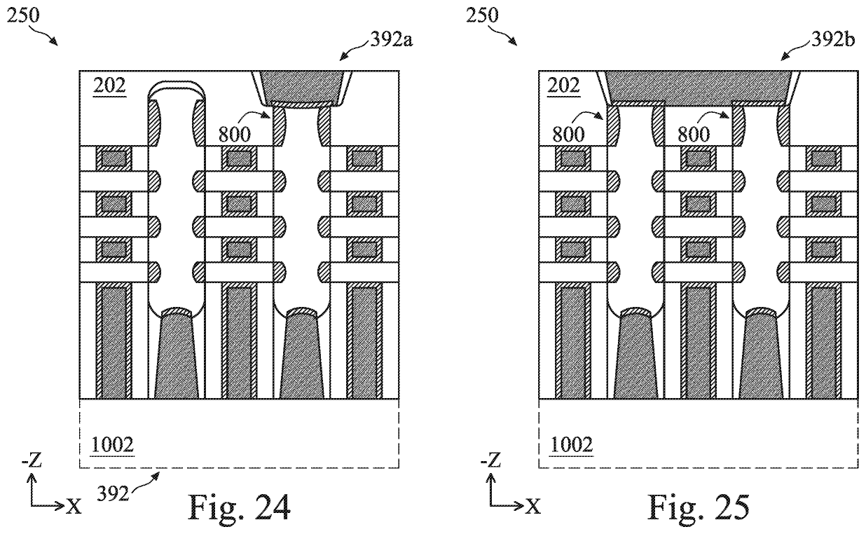

The method 100 may perform further steps to complete fabrication of the semiconductor device 200. Additional operations can be provided before, during, and after method 100, such as forming another backside contact under another one of the source/drain features 800. Further, some of the operations described can be moved, replaced, or eliminated for additional embodiments of method 100. For example, FIGS. 24-25 illustrate cross-sectional views of semiconductor devices 200 having backside vias 392 according to other embodiments of the present disclosure. FIG. 24 shows a semiconductor workpiece 250 substantially similar to the one shown in FIG. 23A, except that the backside via 392a is enlarged to have a greater width in the x direction than the source/drain feature 800 in the x direction. FIG. 25 shows a semiconductor workpiece 250 substantially similar to the one shown in FIG. 23A, except that the backside via 392b is a via rail that contacts multiple source/drain features 800 by extending lengthwise in the x direction.

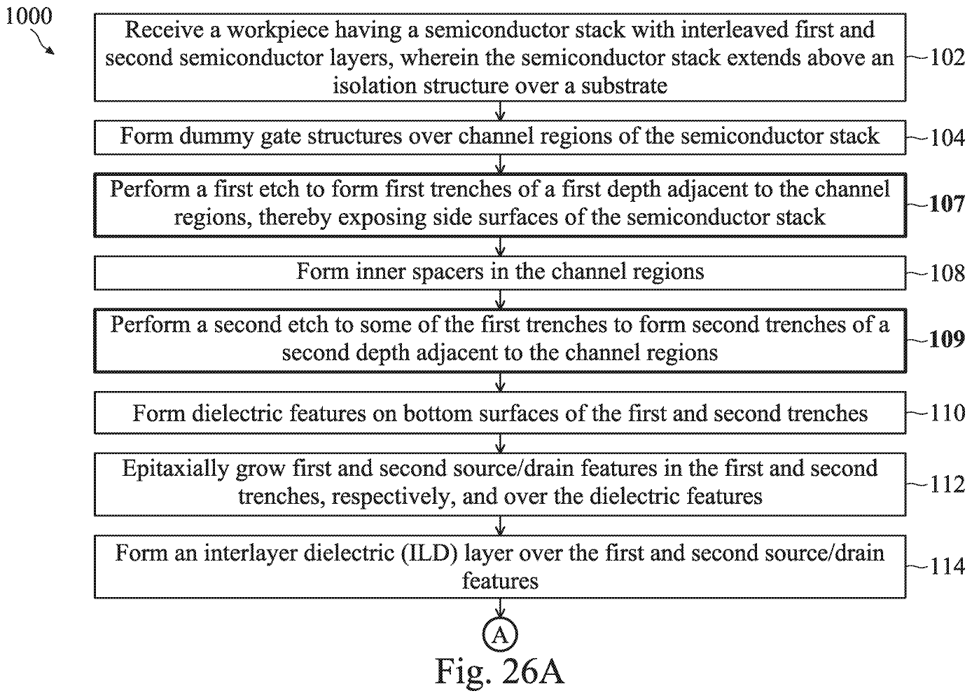

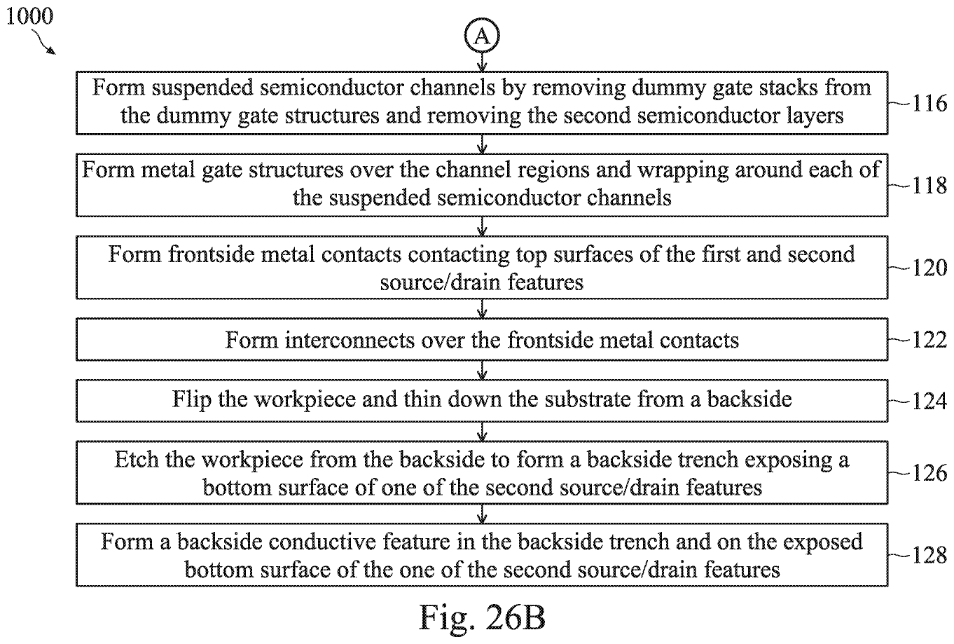

FIGS. 26A-26B is a flow chart of a method 1000 to form a semiconductor device 200 having a backside via, in portion or in entirety, according to various aspects of the present disclosure. Method 1000 is similar to method 100, and the similar operation steps will not be repeated for the sake of brevity. The difference in method 1000 is that instead of forming only deep trenches 212, the method 1000 forms first trenches of a first depth (shallow trenches) and second trenches of a second depth (deep trenches), where the second trenches are like the deep trenches 212 as described with respect to method 100. Specifically, at operation 107, the method 1000 performs a first etch to form first trenches of a first depth adjacent to the channel regions CR. And at operation 109, the method 1000 performs a second etch to some of the first trenches to form second trenches of a second depth. The other operation steps substantially mirror the operations described above in method 100. However, note that the formation of the different features is now with respect to the first trenches and the second trenches.

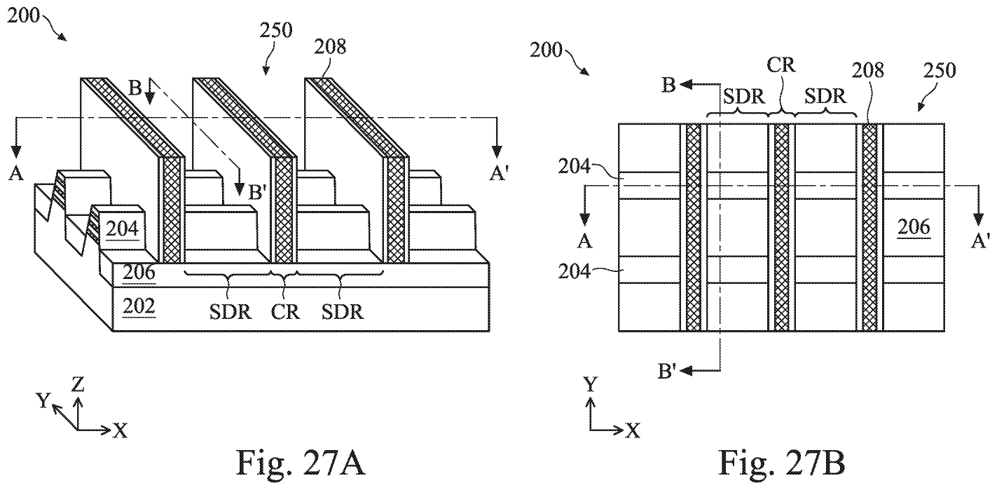

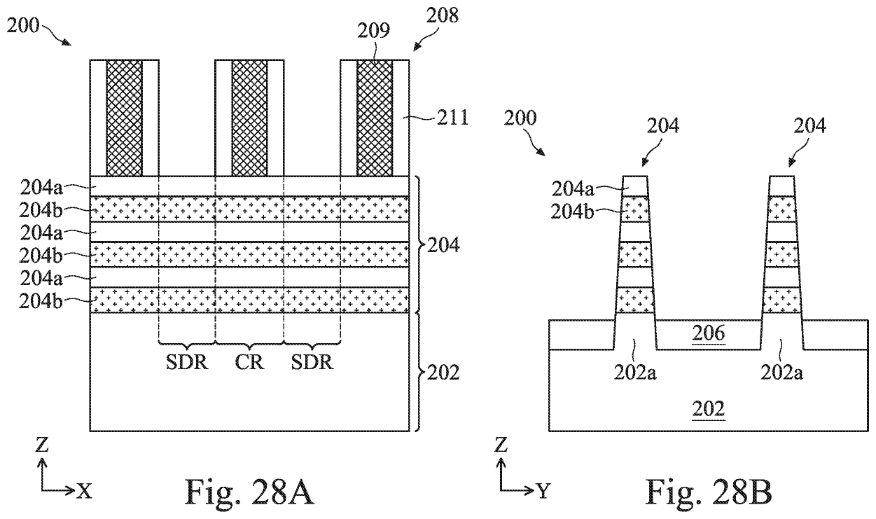

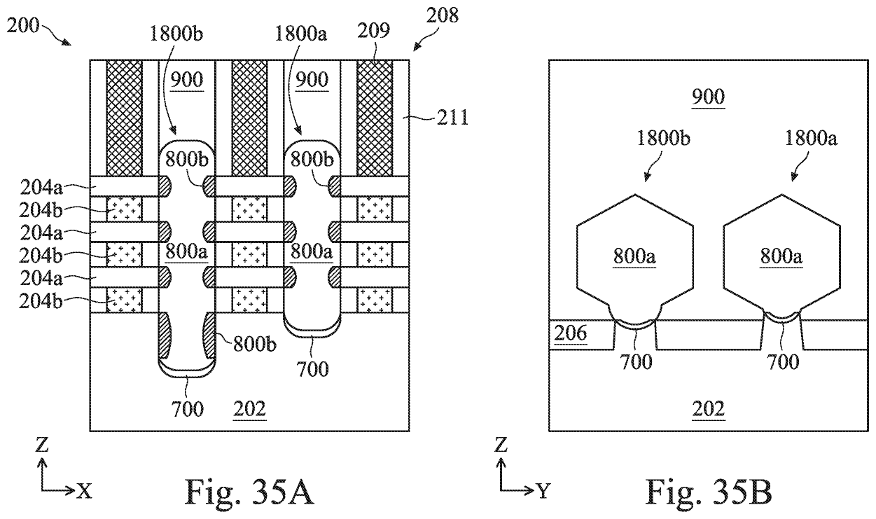

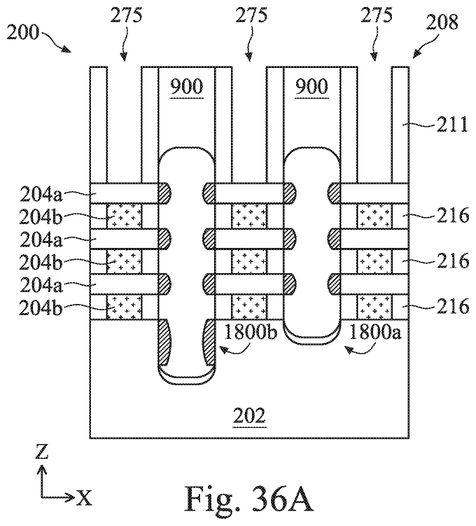

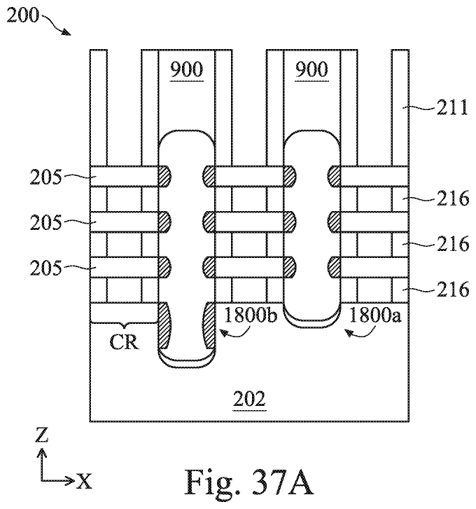

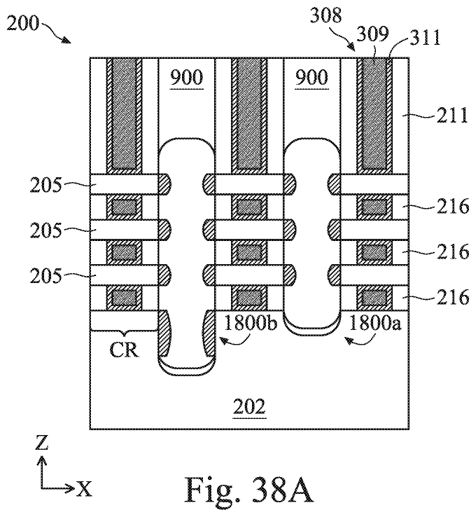

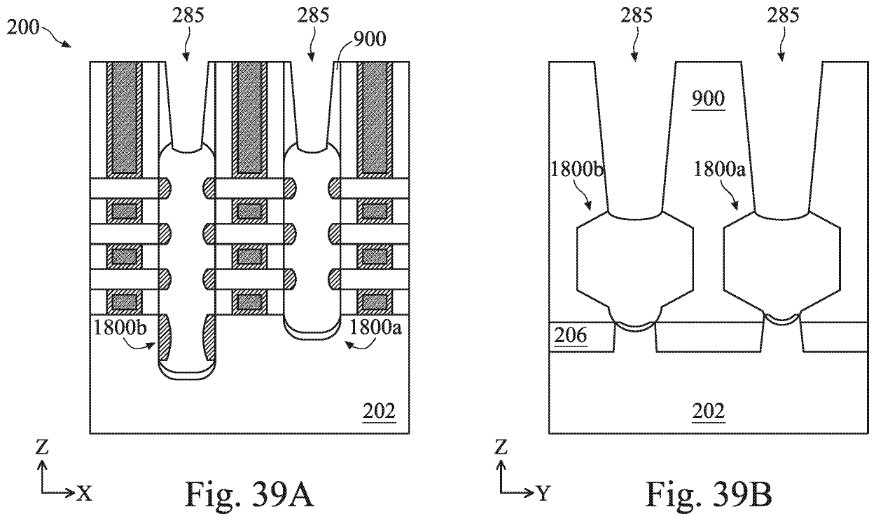

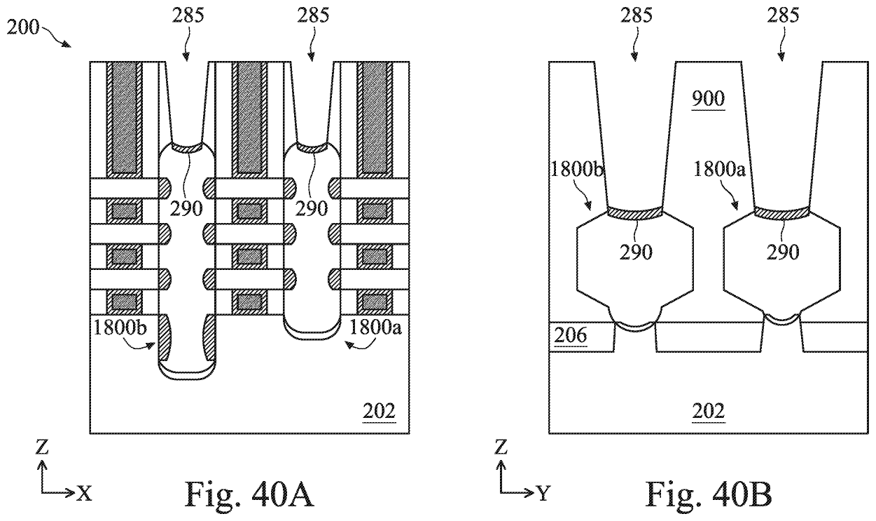

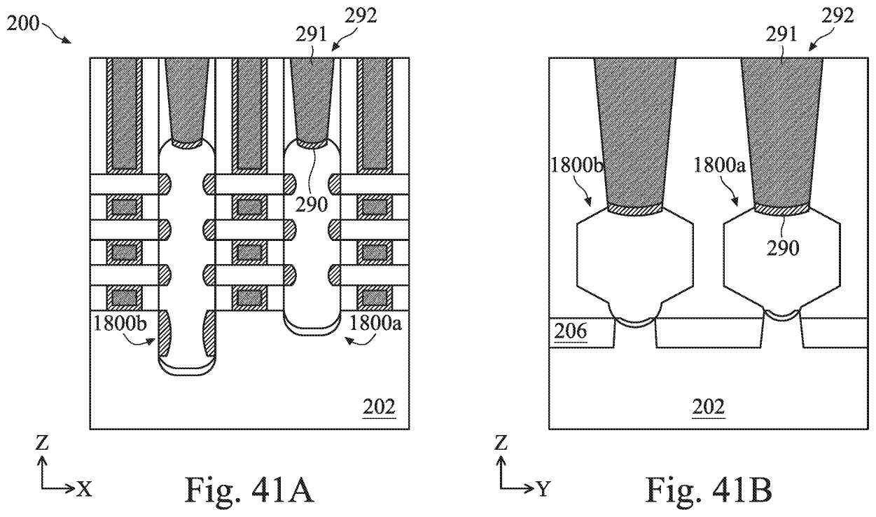

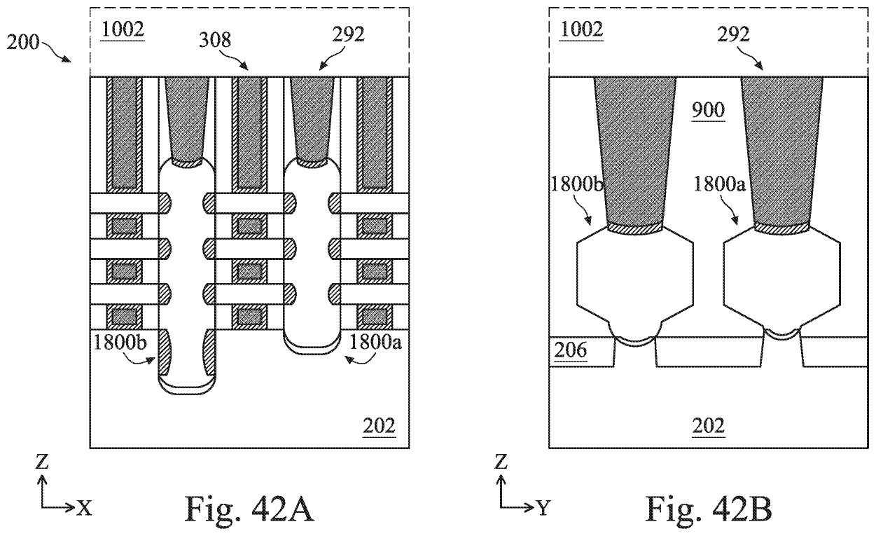

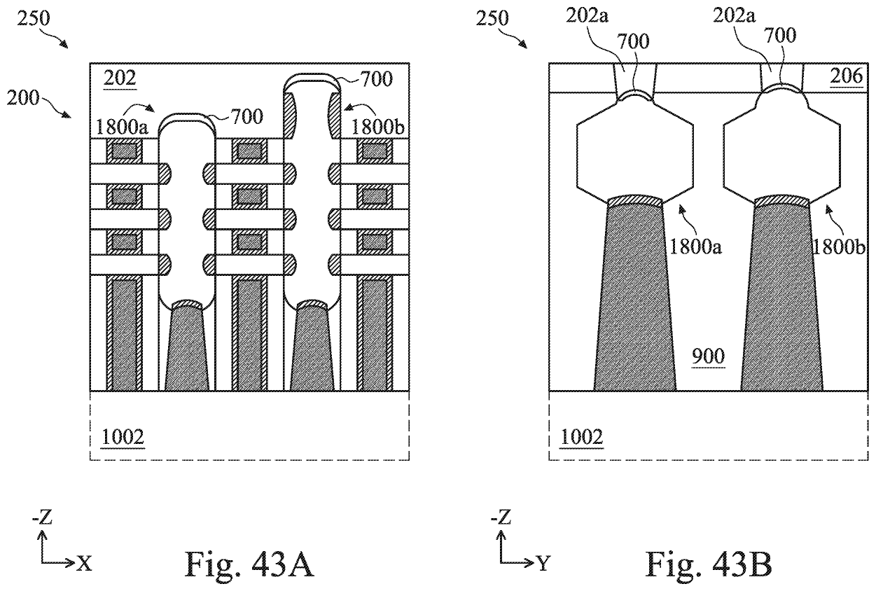

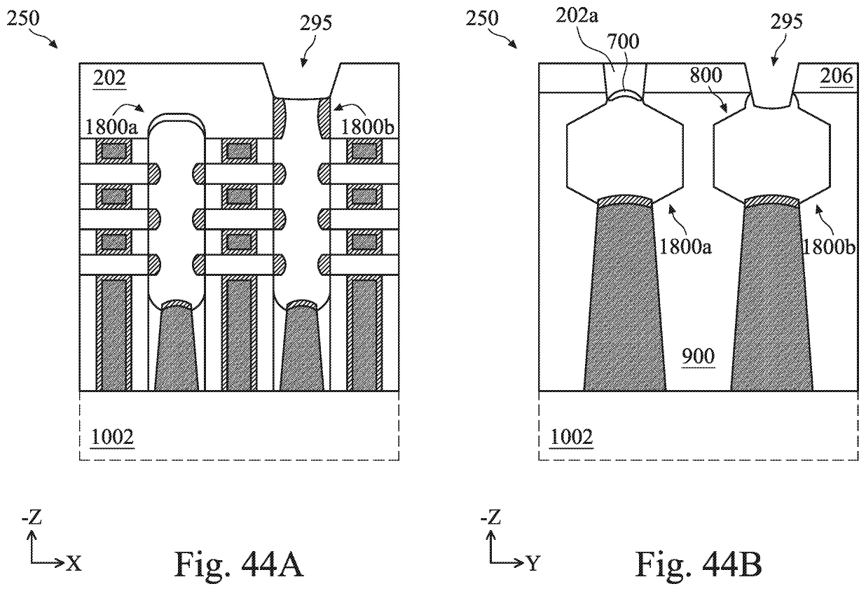

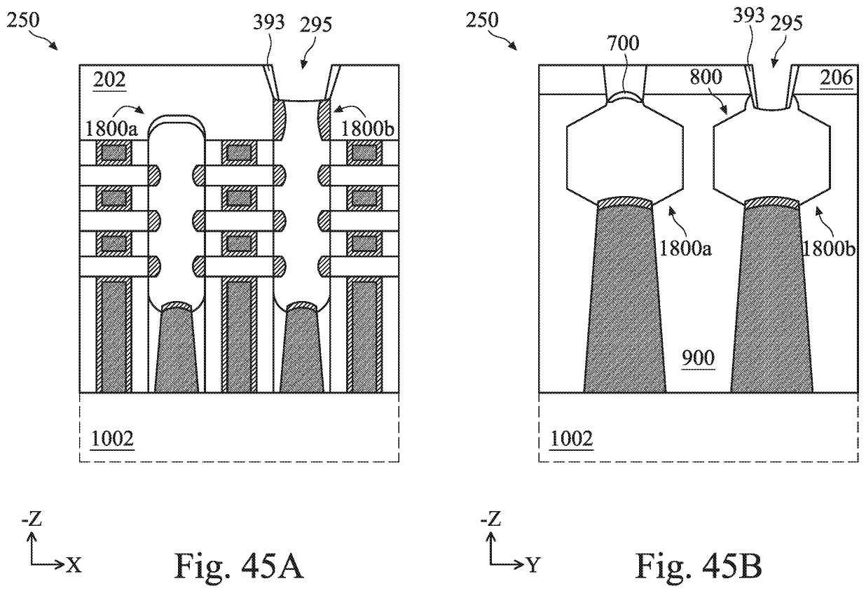

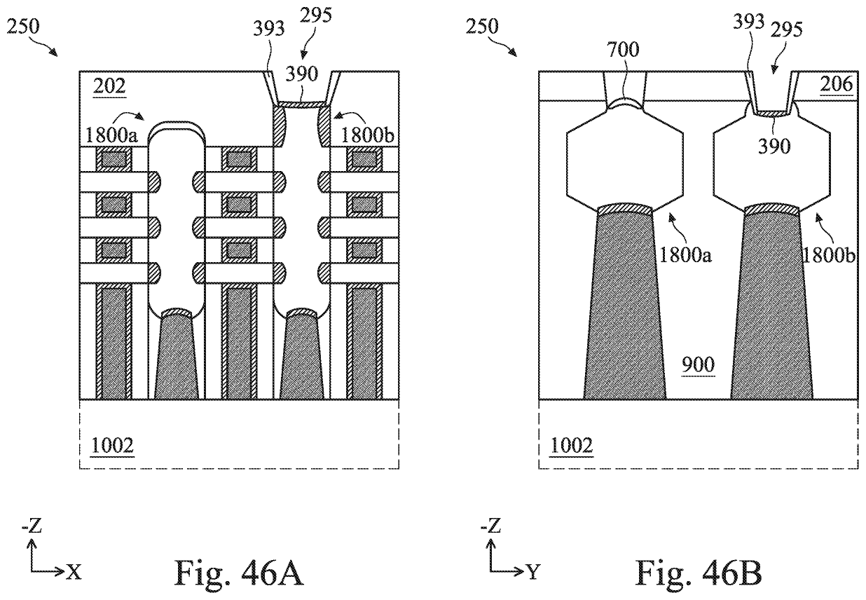

Method 1000 is further described below in conjunction with FIGS. 28A-47A depicting cross-sectional views of a semiconductor device 200 cut along the lines A-A′ in FIGS. 27A and 27B, and FIGS. 28B-29B, 32B-35B, and 39B-47B depicting cross-sectional views of a semiconductor device 200 cut along the lines B-B′ in FIGS. 27A and 27B. These figures illustrate various views of the semiconductor device 200 at intermediate stages of fabrication and processed according to an embodiment of the present disclosure. To the extent that method 1000 differ from method 100, FIGS. 27A-47A and FIGS. 27B-29B, 32B-35B, and 39B-47B will now be described in more detail.

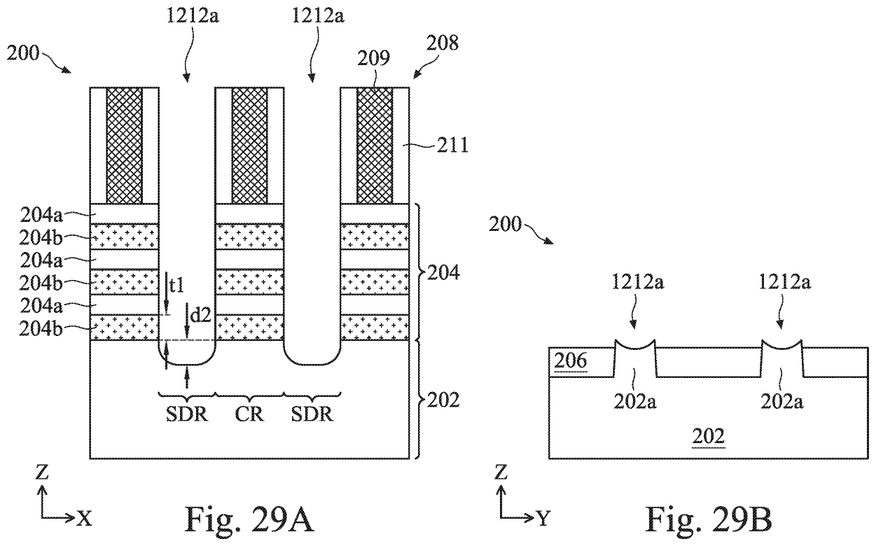

At operation 107, the method 1000 performs a first etch to form first trenches 1212a in the source drain regions SDR adjacent to the channel regions CR of the device 200, an embodiment of which is illustrated in FIGS. 29A and 29B. The first trenches 1212a may also be referred to as first source/drain trenches (recesses) and have sidewalls defined by the remaining portions of the semiconductor stacks 204. The first trenches 1212a may be formed by a dry etching process, a wet etching process, other suitable etching process, or combinations thereof. In some embodiments, the etching process is a multi-step etch process. For example, the etching process may include alternative etchants to separately and alternately remove semiconductor layers 204a and semiconductor layers 204b. In some embodiments, parameters of the etching process are configured to selectively etch semiconductor stacks 204 with minimal (to no) etching of dummy gate structures 208 (i.e., dummy gate stacks 209 and gate spacers 211). In some embodiments, a lithography process is performed to form a patterned mask layer that covers dummy gate structures 208 and/or portions of the isolation structures 206, and the etching process uses the patterned mask layer as an etch mask.

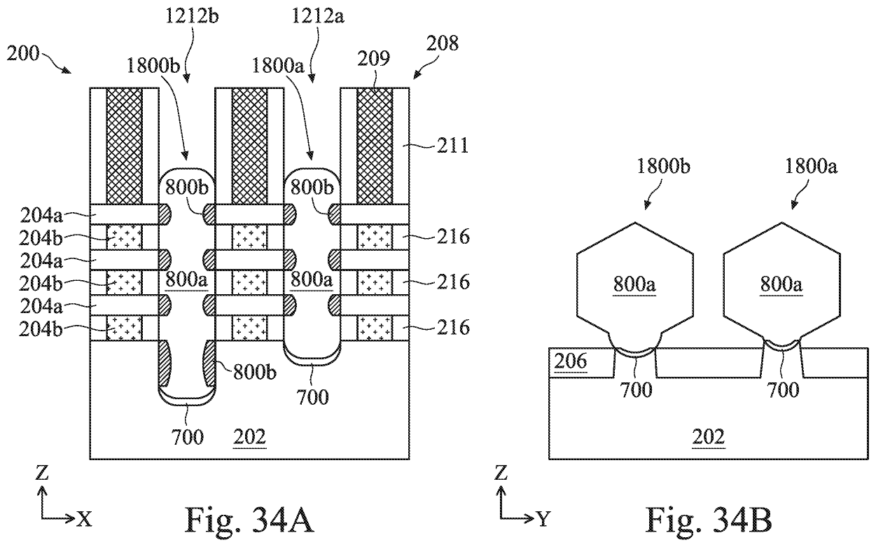

Referring to FIG. 29A, the first trenches 1212a (like the deep trenches 212 in FIG. 4A) extend into the substrate 202 past the bottommost semiconductor layers 204b of the semiconductor stacks 204. As shown, a distance d2 represents an etch distance between the bottommost semiconductor layer 204b and the bottommost surface of the first trenches 1212a. Note that the distance d2 is less than the distance d1 (see the deep trenches 212 in FIG. 4A). A ratio between the distance d2 to a thickness t1 of one of the first or second semiconductor layers 204a or 204b may be in a range of 0 to 2. The distance d2 may be in a range between 5 to 20 nm, and the thickness t1 may be in a range of 5-15 nm. The distance d2 need not be deep, as long as the side surfaces of the bottommost semiconductor layers 204b is exposed and that referring to FIG. 34A, a subsequent source/drain feature 800 in the first trenches 1212a makes contact with a bottommost inner spacer 216. In some embodiments, the distance d2 is the thickness of a dielectric feature 700 that will be deposited into the first trenches 1212a. In other embodiments, the distance d2 is about the same as the thickness t1. Referring now to FIG. 29B, in some embodiments, when the distance d2 is not so deep, the first trenches 1212a do not extend below a top surface of the isolation structure 206. As such, after the first etch to form the first trenches 1212a, much of the protruding portions 202a of the substrate 202 remains.

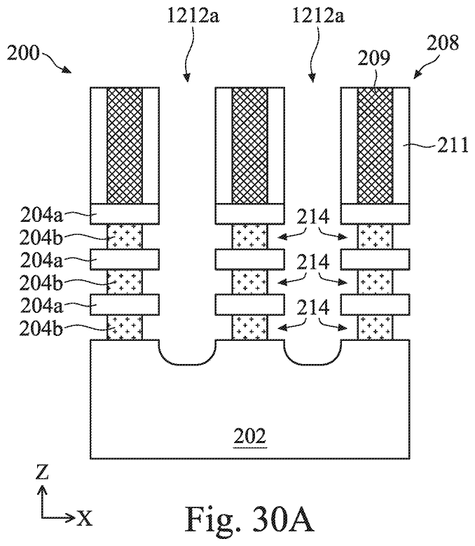

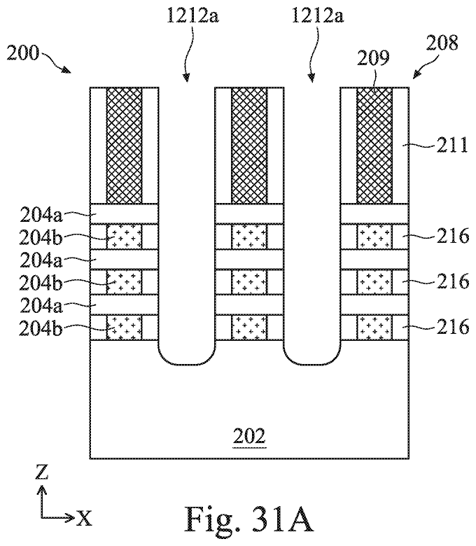

At operation 108, the method 1000 forms inner spacers 216 in substantially the same way as method 100, except that the trenches 1212a at this step are shallower (see FIGS. 30A-31A). In an alternative embodiment, operation 108 may be performed after operation 109. That is, the inner spacers 216 are formed after both the first trenches 1212a and the second trenches 1212b are formed.

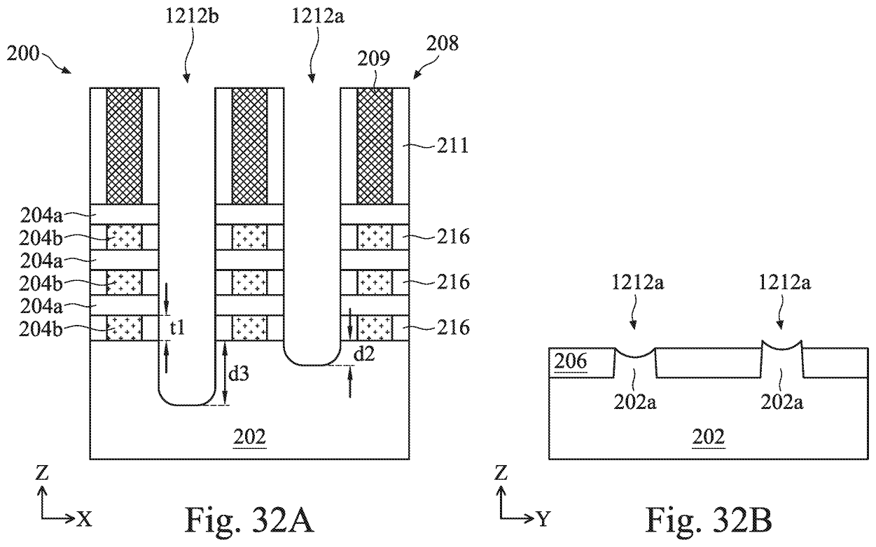

At operation 109, the method 1000 performs a second etch to form second trenches 1212b of a second depth deeper than the first trenches 1212a. FIGS. 32A and 32B illustrate an embodiment showing a second trench 1212b formed next to a first trench 1212a. The second trenches 1212b may also be referred to as second source/drain trenches (recesses) and are formed by a second etch etching further one or more of the first trenches 1212a. The second etch process may be done by using a lithography and patterning process similar to the first etch process.

Still referring to FIG. 32A, the second trenches 1212b are structurally like the deep trenches 212 of FIG. 4A. That is, the second trenches 1212b have an etch distance d3 about equal to the etch distance d1. As shown, d3 is a distance between the bottommost inner spacer 216 or first or second semiconductor layers 204a or 204b and the bottommost surface of the second trenches 1212b. The etch distance d3 is greater than the etch distance d2. A ratio between the distance d3 to d2 may be in a range of 2 to 3. The distance d3 may be in a range between 20 to 50 nm, and the distance d2 may be in a range between 5 to 20 nm. The reasons for the etch distance d3 is the same as for the etch distance d1 with respect to FIG. 4A. Now referring to FIG. 32B, in some embodiments, the first trenches 1212a do not extend below a top surface of the isolation structure 206 but the second trenches 1212b extend below a top surface of the isolation structure 206.

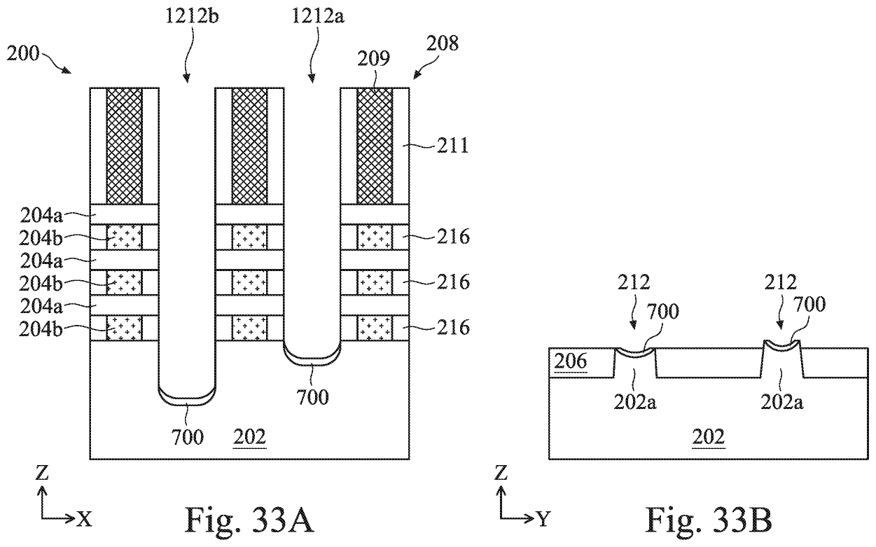

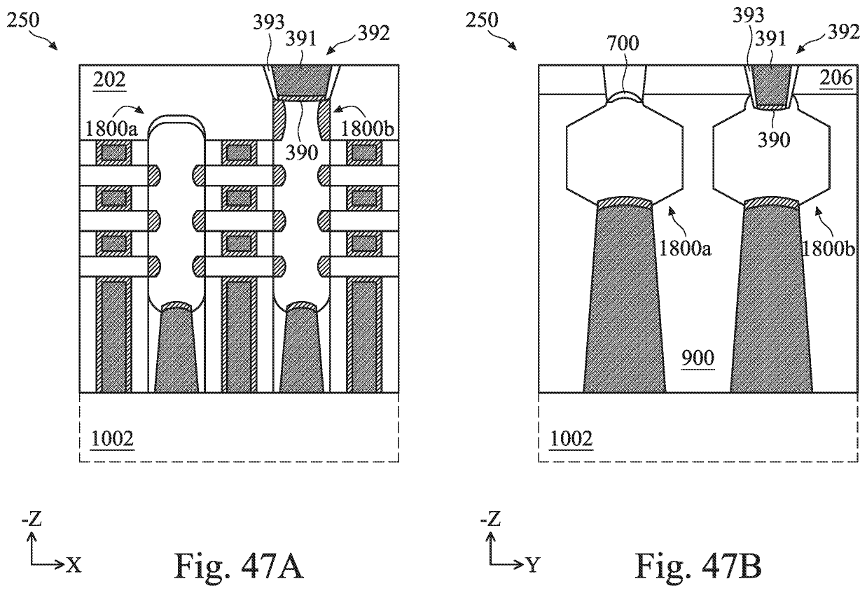

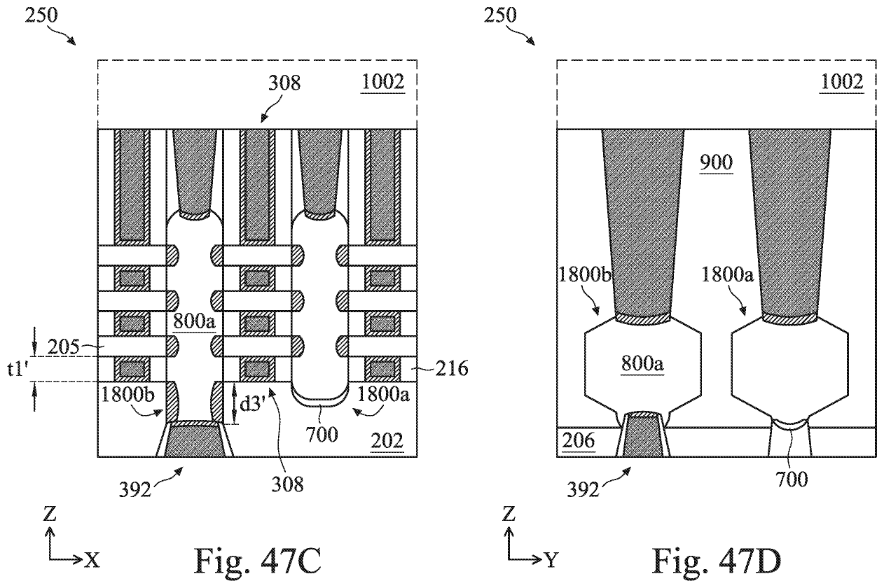

Referring back to the method 1000, the rest of the operations 110 to 128 are similar to that of method 100, with intermediate process steps shown in FIGS. 33A-47A and FIGS. 33B-35B and 39B-47B. The difference here is that first source/drain features 1800a are formed in the first trenches 1212a and second source/drain features 1800b are formed in the second trenches 1212b. Further, the backside contacts (or vias) 392 are only formed under the second source/drain features 1800b as shown in FIGS. 47A and 47B.

Referring now to FIGS. 47C and 47D, after operation 128 of the method 1000, the workpiece 250 is flipped back to the x-z and y-z axis for purposes of illustration and describing relevant features. As shown, the backside metal contact 392 (or backside via) is vertically distanced from the metal gate structure 308 by a distance d3′. The distance d3′ is smaller than the etch distance d3 (see FIG. 32A) due to the dielectric feature 700 being etched away to expose the bottom of the source/drain feature 1800b. Specifically, the distance d3′ is a spacing between the bottommost gate portion of the metal gate structure 308 and the topmost surface of the backside metal contact 392. The bottommost gate portion of the metal gate structure 308 is below the bottommost channel layer 205 and above a top surface of the substrate 202. A ratio between the distance d3′ to a thickness t1′ is in a range of 1 to 3. The thickness t1′ is similar to the thickness t1 (see FIG. 32A), which may correspond in FIG. 47C to a thickness of the channel layers 205, the inner spacers 216, or the gate portions of the metal gate structure 308 between the channel layers 205. The distance d3′ may be in a range between 5 to 30 nm, and the thickness t1′ may be in a range of 5-15 nm. However, d3′ must be at least equal to or greater than t1′ to ensure the minimum ratio of d1′ to t1′. For example, if the thickness t1′ of the inner spacers 216 or channel layers 205 is to be 5 nm, the distance d3′ must also be at least 5 nm. This is because a sufficient distance d3′ is necessary to ensure proper spacing and insulation between the backside via 392 and the bottommost portion of the metal gate structure 308. The extra spacing prevents unwanted current leakage and possibility of shorting between gate and source/drain features. However, excessive spacing, such as a ratio of d3′ to t1 greater than 3 is also not desirable because this will unnecessarily enlarge device footprint. As long as the benefit of gate to backside via isolation is achieved, any excessive spacing (e.g., d3′/t1′ greater than 3) will only incur additional cost and space. Note that in the y-z plane, a top surface of the backside via 392 may extend into the heavily doped layer 800a of the source/drain feature 800, such that the top surface of the backside via 392 is above the top surface of the isolation structure 206.

Still referring to FIGS. 47C and 47D, only second source/drain features 1800b are connected to backside vias 392 because they have a sufficient spacing d3′ that isolate the backside vias 392 from the gate structures 308. On the other hand, first source/drain features 1800a are not connected to backside vias 392 due to insufficient spacing to isolate from the gate structures 308. The dielectric cap 700 that remains provides proper insulation to prevent stray conductance between the first source/drain features 1800a and other metal connections on the backside. The first source/drain features 1800a having a shallower depth into the substrate 202 is also advantageous for further separation and isolation from other backside metal features. For the source/drain features 1800b, the etched away dielectric cap 700 acts as an etch stop layer for proper etch height when forming backside trenches 295 and backside vias 392. Since the distance between the backside vias 392 and the metal gate structures 308 is sensitive, without the dielectric caps 700, there would be difficulty controlling the distance d3′ and undesirable over-etching may occur. With the dielectric caps 700, the proper distance d3′ can be controlled to ensure the benefits of proper isolation between the metal gate structures 308 and the backside vias 392. Note that the bottommost portion of the source/drain features 1800b (i.e., portion in contact with the backside vias 392) is below the bottommost portion of the source/drain features 1800a. In some embodiments, the bottommost portion of the source/drain features 1800b is also below the bottommost portion of the dielectric caps 700.

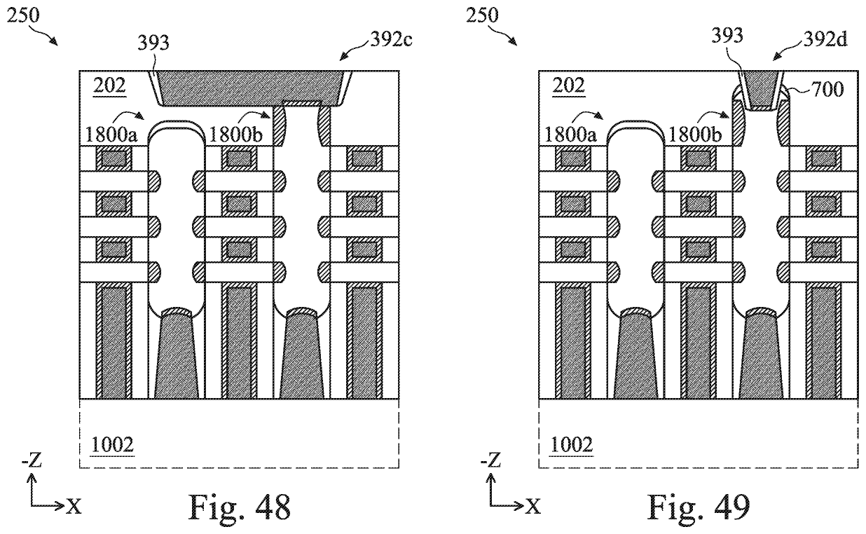

The method 1000 may perform further steps to complete fabrication of the semiconductor device 200. Additional operations can be provided before, during, and after method 100, and some of the operations described can be moved, replaced, or eliminated for additional embodiments of method 100. For example, FIGS. 48-51 illustrate cross-sectional views of semiconductor devices 200 having backside vias according to other embodiments of the present disclosure according to method 1000.

FIG. 48 shows a semiconductor workpiece 250 substantially similar to the one shown in FIG. 47A, except that the backside via 392c is enlarged to have a greater width in the x direction than the source/drain feature 1800b in the x direction. In some embodiments, the backside via 392c is a via rail that connects multiple second source/drain features 1800b without connecting to the first source/drain features 1800a. This is possible due to the height differences in the z direction between the first source/drain features 1800a and 1800b. As such, the backside via rail 392c may cover the first source/drain features 1800a when viewed along the negative z direction.

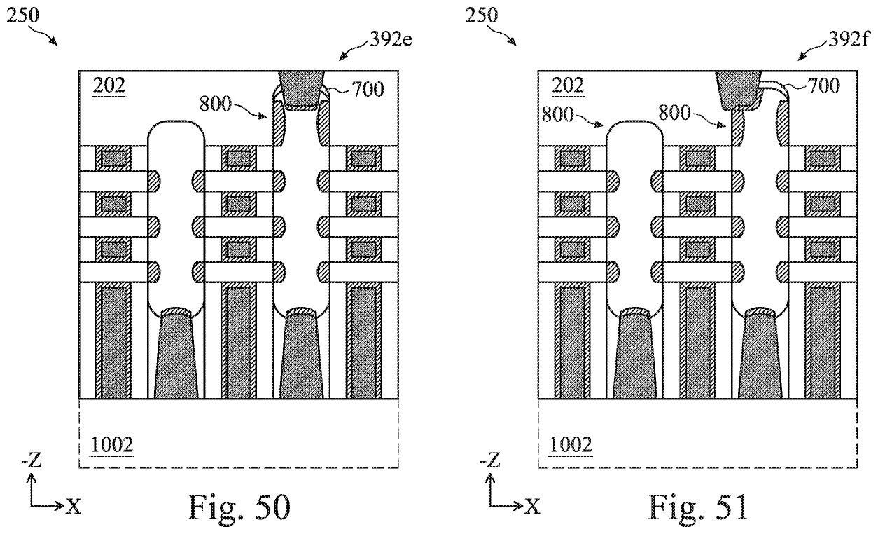

FIG. 49 shows a semiconductor workpiece 250 substantially similar to the one shown in FIG. 47A, except that the backside via 392d has a smaller width in the x direction than the source/drain feature 1800b in the x direction. Note that in this embodiment, a portion of the dielectric feature 700 remains even after the etch-through and filling of the backside trench 295. The embodiment shown in FIG. 50 is similar to FIG. 49, except that the backside via 392e is not lined with barrier layers 393. The embodiment shown in FIG. 51 is similar to FIG. 50, except that the backside via 392f has an overlay shift. As shown in FIGS. 49-51, the present disclosure contemplates backside vias with or without barrier layers as well as having partial dielectric features 700 still remaining even after the forming of the backside vias.

Although not limiting, the present disclosure offers advantages for semiconductor devices having backside vias. One example advantage is that the backside vias are formed to have sufficient separation from metal gate structures on the back side. The separation prevents unwanted current leakage between source/drain features and metal gates. Another example advantage is using dielectric caps when forming backside vias, thereby providing proper etch distance. Another example advantage is to use the dielectric caps as insulation layers for source/drain features without a backside via, thereby isolating these source/drain features from other metal features on the back side. Another example advantage is to form source/drain features having different depths to control formation of backside vias or backside via rails.

One aspect of the present disclosure pertains to a method of forming a semiconductor device. The method includes receiving a workpiece having an active region extending from a substrate, the active region is surrounded by an isolation structure, and portions of the active region protrudes above a top surface of the isolation structure. The method includes forming a gate stack over a channel region of the active region and forming a first source/drain (S/D) trench adjacent the channel region and extending into the substrate below a top surface of the isolation structure. The method includes forming a first epitaxial S/D feature in the first S/D trench and forming a first frontside metal contact over the first epitaxial S/D feature. The method includes forming a first backside trench that exposes a bottom surface of the first epitaxial S/D feature and forming a first backside conductive feature in the first backside trench and on the exposed bottom surface of the first epitaxial S/D feature. A top surface of the first backside conductive feature is under a bottommost surface of the gate stack.

In an embodiment, the method further includes forming a second S/D trench adjacent the channel region and extending into the substrate below the top surface of the isolation structure. The method further includes forming a second epitaxial S/D feature in the second S/D trench and forming a second frontside metal contact over the second epitaxial S/D feature.

In a further embodiment, the method further includes forming a second backside trench that exposes a bottom surface of the second epitaxial S/D feature; and forming a second backside conductive feature in the second backside trench and on the exposed bottom surface of the second epitaxial S/D feature, where a top surface of the second backside conductive feature is formed under the bottommost surface of the gate stack. In another embodiment, the first backside trench further exposes a bottom surface of the second epitaxial S/D feature, and the first backside conductive feature extends along a direction to also form on the exposed bottom surface of the second epitaxial S/D feature.

In an embodiment, the method further comprises forming a second S/D trench adjacent the channel region, where the forming of the first S/D trench includes selectively etching the first S/D trench to be deeper than the second S/D trench.

In an embodiment, before the forming of the first epitaxial S/D feature, the method further includes forming a dielectric feature on a bottom surface of the first S/D trench. Ant the forming of the dielectric feature includes conformally depositing a dielectric layer into the first S/D trench, performing a plasma treatment on a top surface of the dielectric layer, selectively etching away the dielectric layer on sidewalls of the first S/D trench.

In a further embodiment, the forming of the first backside trench includes etching through the dielectric feature in the first S/D trench. In a further embodiment, after the forming of the first backside conductive feature, a portion of the dielectric feature remains over a bottom surface of the first epitaxial S/D feature.

In an embodiment, the forming of the first backside conductive feature further includes forming a dielectric barrier layer along sidewalls of the first backside trench. In an embodiment, the first epitaxial S/D feature has a lightly doped outer layer and a heavily doped inner layer, and the first backside conductive feature is in direct contact with the heavily doped inner layer of the first epitaxial S/D feature.

Another aspect of the present disclosure pertains to a method of forming a semiconductor device. The method includes receiving a semiconductor stack having interleaved first and second semiconductor layers, where the semiconductor stack extends above an isolation structure over a substrate. The method includes performing a first etching process to first and second S/D regions of the semiconductor stack to form first S/D trenches exposing side surfaces of the semiconductor stack. The method includes performing a second etching process to only the second S/D regions of the semiconductor stack to form second S/D trenches that penetrate deeper into the substrate than the first S/D trenches. The method includes forming first dielectric features on bottom surfaces of the first S/D trenches. After forming the first dielectric features, the method includes forming first and second S/D features in the first and second S/D trenches, respectively. The method includes removing the second semiconductor layers from the semiconductor stack to form suspended semiconductor channels in a channel region of the semiconductor stack. The method includes forming a metal gate structure over the channel region and wrapping around each of the suspended semiconductor channels to form wrapped semiconductor channels. And the method includes forming backside S/D trenches by etching from a backside of the substrate to expose bottom surfaces of the second S/D features. Each of the exposed bottom surfaces is below a bottommost portion of the metal gate structure wrapping around a bottommost layer of the wrapped semiconductor channels.

In an embodiment, the method further includes forming a backside via on a bottom surface of one of the second S/D features. In another embodiment, before forming of the first and second S/D features, the method includes forming second dielectric features in the second S/D trenches, where forming the backside S/D trenches includes etching through the second dielectric features in the second S/D trenches.

In an embodiment, the forming of the metal gate structure includes forming a dummy gate stack over the channel region of the semiconductor stack. And before the performing of the second etching process, the method includes performing a side etch on sidewalls of each of the second semiconductor layers in the first S/D trenches, thereby forming air gaps. The method as part of forming the metal gate structure further includes forming inner spacers in the air gaps, removing the dummy gate stack to expose side surfaces of the semiconductor stack, and after the removing of the second semiconductor layers, replacing the dummy gate stack and each of the removed second semiconductor layers with a metal gate feature.

Another aspect of the present disclosure pertains to a semiconductor device. The semiconductor device includes an active region protruding from a substrate and disposed between portions of an isolation structure. The semiconductor device includes a gate stack disposed on a channel region of the active region. The semiconductor device includes a source/drain (S/D) feature over a source/drain region of the active region, where the S/D feature has an entrenched portion that extends below a top surface of the substrate. The semiconductor device includes a backside silicide layer on a bottom surface of the S/D feature. And the semiconductor device includes a backside via on a bottom surface of the backside silicide layer, where a top surface of the backside via is below a bottommost portion of the gate stack.

In an embodiment of the semiconductor device, the S/D feature has a lightly doped outer layer and a heavily doped inner layer, and the backside via is in electrical contact with the heavily doped inner layer by directly contacting the backside silicide layer.

In an embodiment of the semiconductor device, a width of the backside via along a lengthwise direction of the active region is smaller than a width of the S/D feature. In a further embodiment, the semiconductor device further includes a silicon nitride cap on a first portion of the bottom surface of the S/D feature, where the backside via is disposed on a second portion of the bottom surface of the S/D feature.

In an embodiment, the semiconductor device further includes a silicon nitride barrier layer on sidewalls of the backside via.

In an embodiment of the semiconductor device, the S/D feature is a first S/D feature, and the semiconductor device further comprises a second S/D feature over a second source/drain region of the active region and a backside dielectric cap on a bottom surface of the second S/D feature. And the bottom surface of the of the first S/D feature is below the bottom surface of the second S/D feature.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method of forming a semiconductor device, comprising:
receiving a workpiece having an active region extending from a substrate, the active region is surrounded by an isolation structure, and portions of the active region protrudes above a top surface of the isolation structure;
forming a gate stack over a channel region of the active region;
forming a first source/drain (S/D) trench adjacent the channel region and extending into the substrate below a top surface of the isolation structure;
forming a first epitaxial S/D feature in the first S/D trench;
forming a first frontside metal contact over the first epitaxial S/D feature;
forming a first backside trench that exposes a bottom surface of the first epitaxial S/D feature; and
forming a first backside conductive feature in the first backside trench and on the exposed bottom surface of the first epitaxial S/D feature, wherein a top surface of the first backside conductive feature is under a bottommost surface of the gate stack.

2. The method of claim 1, further comprising:
forming a second S/D trench adjacent the channel region and extending into the substrate below the top surface of the isolation structure;
forming a second epitaxial S/D feature in the second S/D trench; and
forming a second frontside metal contact over the second epitaxial S/D feature.

3. The method of claim 2, further comprising:
forming a second backside trench that exposes a bottom surface of the second epitaxial S/D feature; and
forming a second backside conductive feature in the second backside trench and on the exposed bottom surface of the second epitaxial S/D feature, wherein a top surface of the second backside conductive feature is formed under the bottommost surface of the gate stack.

4. The method of claim 2,
wherein the first backside trench further exposes a bottom surface of the second epitaxial S/D feature,
wherein the first backside conductive feature extends along a direction to also form on the exposed bottom surface of the second epitaxial S/D feature.

5. The method of claim 1, further comprising forming a second S/D trench adjacent the channel region, wherein the forming of the first S/D trench includes selectively etching the first S/D trench to be deeper than the second S/D trench.

6. The method of claim 1, further comprising:
before the forming of the first epitaxial S/D feature, forming a dielectric feature on a bottom surface of the first S/D trench,
wherein the forming of the dielectric feature includes:
conformally depositing a dielectric layer into the first S/D trench,
performing a plasma treatment on a top surface of the dielectric layer, and
selectively etching away the dielectric layer on sidewalls of the first S/D trench.

7. The method of claim 6, wherein the forming of the first backside trench includes etching through the dielectric feature in the first S/D trench.

8. The method of claim 7, wherein after the forming of the first backside conductive feature, a portion of the dielectric feature remains over a bottom surface of the first epitaxial S/D feature.

9. The method of claim 1, wherein the forming of the first backside conductive feature further includes forming a dielectric barrier layer along sidewalls of the first backside trench.

10. The method of claim 1, wherein the first epitaxial S/D feature has a lightly doped outer layer and a heavily doped inner layer, and the first backside conductive feature is in direct contact with the heavily doped inner layer of the first epitaxial S/D feature.

11. A method of forming a semiconductor device, comprising:
receiving a semiconductor stack having interleaved first and second semiconductor layers, wherein the semiconductor stack extends above an isolation structure over a substrate;
performing a first etching process to first and second S/D regions of the semiconductor stack to form first S/D trenches exposing side surfaces of the semiconductor stack;
performing a second etching process to only the second S/D regions of the semiconductor stack to form second S/D trenches that penetrate deeper into the substrate than the first S/D trenches;
forming first dielectric features on bottom surfaces of the first S/D trenches;
after forming the first dielectric features, forming first and second S/D features in the first and second S/D trenches, respectively;
removing the second semiconductor layers from the semiconductor stack to form suspended semiconductor channels in a channel region of the semiconductor stack;
forming a metal gate structure over the channel region and wrapping around each of the suspended semiconductor channels to form wrapped semiconductor channels; and
forming backside S/D trenches by etching from a backside of the substrate to expose bottom surfaces of the second S/D features, wherein each of the exposed bottom surfaces is below a bottommost portion of the metal gate structure wrapping around a bottommost layer of the wrapped semiconductor channels.

12. The method of claim 11, further comprising forming a backside via on a bottom surface of one of the second S/D features.

13. The method of claim 11, further comprising:
before the forming of the first and second S/D features, forming second dielectric features in the second S/D trenches, wherein forming the backside S/D trenches includes etching through the second dielectric features in the second S/D trenches.

14. The method of claim 11, wherein forming the metal gate structure includes:
forming a dummy gate stack over the channel region of the semiconductor stack;
before the performing of the second etching process, performing a side etch on sidewalls of each of the second semiconductor layers in the first S/D trenches, thereby forming air gaps;
forming inner spacers in the air gaps;
removing the dummy gate stack to expose side surfaces of the semiconductor stack; and
after the removing of the second semiconductor layers, replacing the dummy gate stack and each of the removed second semiconductor layers with a metal gate feature.

15. A semiconductor device, comprising:
an active region protruding from a substrate and disposed between portions of an isolation structure;
a gate stack disposed on a channel region of the active region;
a source/drain (S/D) feature over a source/drain region of the active region, wherein the S/D feature has an entrenched portion that extends below a top surface of the substrate;
a backside silicide layer on a bottom surface of the S/D feature; and
a backside via on a bottom surface of the backside silicide layer, wherein a top surface of the backside via is below a bottommost portion of the gate stack.

16. The semiconductor device of claim 15, wherein the S/D feature has a lightly doped outer layer and a heavily doped inner layer, and the backside via is in electrical contact with the heavily doped inner layer by directly contacting the backside silicide layer.

17. The semiconductor device of claim 15, wherein a width of the backside via along a lengthwise direction of the active region is smaller than a width of the S/D feature.

18. The semiconductor device of claim 17, further comprising a silicon nitride cap on a first portion of the bottom surface of the S/D feature, wherein the backside via is disposed on a second portion of the bottom surface of the S/D feature.

19. The semiconductor device of claim 15, further comprising a silicon nitride barrier layer on sidewalls of the backside via.

20. The semiconductor device of claim 15, wherein the S/D feature is a first S/D feature, and the semiconductor device further comprises:
a second S/D feature over a second source/drain region of the active region; and
a backside dielectric cap on a bottom surface of the second S/D feature,
wherein the bottom surface of the of the first S/D feature is below the bottom surface of the second S/D feature.
